(19) United States
(12) Patent Application Publication
(10) Pub. No.: US 2021/0335585 A1
(43) Pub. Date: Oct. 28, 2021

(54) CONTINUOUS FLOW SYSTEM AND METHOD FOR COATING SUBSTRATES

(71) Applicant: SINGULUS TECHNOLOGIES AG, Kahl am Main (DE)

(72) Inventors: Bernhard Cord, Alzenau (DE); Michael Reising, Mömbris (DE); Dieter Scherger, Großwallstadt (DE); Torsten Dippell, Langen (DE); Frank May, Frankfurt am Main (DE); Peter Wohlfart, Kahl am Main (DE); Oliver Hohn, Gründau (DE)

(21) Appl. No.: 17/056,739

(22) PCT Filed: Apr. 4, 2019
(86) PCT No.: PCT/EP2019/058505

§ 371 Date: Apr. 8, 2021

(30) Foreign Application Priority Data
May 18, 2018 (DE) 10 2018 004 086.1

(51) Int. Cl. H01J 37/32; H01L 31/18; H01L 21/677; H01J 37/34; C23C 14/56; C23C 16/54; C23C 16/50; C23C 14/34; C23C 14/06

(52) U.S. Cl. CPC H01J 37/32788; H01L 31/1804; H01L 21/67706; H01L 21/6776; H01J 37/32834; H01J 37/34; H01L 31/022425; C23C 14/568; C23C 16/54; C23C 16/50; C23C 14/3407; C23C 14/0652; C23C 14/566

(57) ABSTRACT

A continuous machine (100) for coating substrates (103) comprises a process module (130) and a vacuum lock (110, 150) for introducing the substrates (103) or removing the substrates (103). The vacuum lock (110, 150) comprises a chamber for receiving a substrate carrier (102) with a plurality of substrates (103) and a flow channel arrangement for evacuating and venting the chamber. The flow channel arrangement comprises a first channel for evacuating and venting the chamber and a second channel for evacuating and venting the chamber, wherein the first channel and the second channel are arranged at opposing sides of the chamber.

### TECHNICAL FIELD

The present invention relates to continuous machines, particularly continuous vacuum plants, and methods, particularly vacuum methods, for coating substrates. The invention particularly relates to continuous machines configured for coating light substrates, particularly silicon wafers. The continuous machines and methods may be configured for the continuous coating of substrates.

### BACKGROUND

Continuous machines for processing substrates are known from, e.g., EP 2 276 057 B1. Substrates are introduced into a vacuum process chamber by means of a substrate transport system and taken out again after having been processed. For this purpose, a horizontal substrate carrier against which the substrates rest along an area is used as a substrate transport system.

US 2013/0031333 A1 discloses an installation for processing a plurality of substrates, said installation comprising locks.

WO 2015/126439 discloses an apparatus and a method for passivating crystalline silicon solar cells. A plurality of process stations is provided consecutively along a transport direction.

DE 10 2012 109 830 A1 discloses a lock chamber which is, on the input or output side, respectively, provided for transferring substrates into or out of a vacuum treatment plant. The lock chamber is configured such that a chamber cover comprises at least one recess with a recess bottom at a distance from the upper edge and such that the suction opening is provided in the chamber cover.

US 2005/0217993 A1 discloses a multistage lock chamber device with at least two lock chambers.

DE 10 2010 040 640 A1 discloses a substrate treatment plant for processing substrates with at least one plant chamber limited by chamber walls, said plant chamber comprising at least one substrate treatment device and at least one pyrometer for determining the temperature of the substrates.

U.S. Pat. No. 7,413,639 B2 discloses an energy and media connection module for coating installations. Said module serves for supplying cooling water, compressed air, process gases, signal, control and cathode power.

DE 10 2016 107 830 A1 discloses a vacuum chamber arrangement with a lock chamber and a process chamber which are coupled to each other by means of a substrate transfer opening, and a transport device for transporting a substrate through the substrate transfer opening.

DE 10 2012 201 953 A1 discloses a method for coating a substrate with an AlOₓ layer.

A cost-effective, efficient processing of substrates, e.g., of crystalline silicon wafers, is of utmost importance in the art. For instance, it enables solar cells to be made more competitive with respect to energy generation. Particularly in continuous machines which comprise a vacuum lock, the cycle times of the vacuum lock may significantly affect the throughput of the plant. Vacuum locks are often configured such that the gas pressure is typically changed between normal pressure and a considerably smaller pressure, e.g., a pressure of less than 100 Pa, in order to introduce substrates into a process line and remove them therefrom. A short cycle time and thus quick evacuation and venting of the vacuum lock are desirable for a high plant throughput.

Conventional approaches to increase the throughput of a continuous machine, particularly to increase the throughput of vacuum locks, often entail an increased complexity and thus make the continuous machine more prone to failure.

### BRIEF DESCRIPTION OF THE INVENTION

There is a need for improved apparatuses and methods for coating substrates in a continuous machine, particularly a continuous vacuum plant. There is a particular need for such apparatuses and methods which enable a coating or a layer system of high quality to be deposited onto substrates, wherein a high throughput of the continuous machine is achieved. There is a need for such apparatuses and methods which comprise short introduction and/or removal times. There is a need for such apparatuses and methods which allow for a long operating time of the continuous machine and/or maintenance intervals that are short in comparison to the operating time.

Continuous machines and methods with the features indicated in the independent claims are provided. The dependent claims define embodiments.

According to one aspect of the invention, a continuous machine for coating substrates is described, which comprises a process module or a plurality of process modules and a vacuum lock for introducing the substrates or removing the substrates. The vacuum lock comprises a chamber for receiving a substrate carrier with a plurality of substrates, and a flow channel arrangement for evacuating and venting the chamber. The flow channel arrangement comprises a first channel for evacuating and venting the chamber, and a second channel for evacuating and venting the chamber, wherein the first channel and the second channel are disposed at opposing sides of the chamber.

In such a continuous machine, the vacuum lock with the substrate carrier disposed therein may be evacuated and/or vented via a plurality of channels. The arrangement of the first and second channels allows for quick evacuation and/or venting, wherein the risk of inadvertently lifting substrates from the substrate carrier is low.

The first channel and the second channel may be spaced apart from each other in a horizontal direction.

The first channel and the second channel may be spaced apart from each other in the transport direction or in a direction running transversely to the transport direction in a horizontal direction. The chamber may comprise two major surfaces which limit the chamber parallel to the substrate plane or the transport plane, and four lateral wall regions.

The flow channel arrangement may be disposed at the lateral wall regions.

Alternatively, the flow channel arrangement may be disposed at the major surfaces adjacent to the lateral wall regions or be incorporated into the major surfaces in regions adjacent to the lateral wall regions.

The flow channel arrangement may comprise a first pair of channels which are disposed at a lateral wall region of the chamber. The first pair may comprise the first channel and an additional first channel. The channels of the first pair of channels may communicate with each other via first overflow orifices. A first slotted plate may be arranged between the channels of the first pair of channels.

The channels of the first pair of channels may be disposed one above the other (i.e., vertically displaced), and/or the first slotted plate may lie in a substantially horizontal plane.

The channels of the first pair of channels may be arranged such that a gas flow between the channels of the first pair of channels takes place in the vertical direction during operation.

The channels of the first pair of channels may be disposed offset in a horizontal direction in a side-by-side arrangement, and/or the first slotted plate may lie in a substantially vertical plane.

The channels of the first pair of channels may be arranged such that a gas flow between the channels of the first pair of channels takes place in the horizontal direction during operation.

The flow channel arrangement may comprise a second pair of channels which are arranged at an additional lateral wall region of the chamber. The second pair may comprise the second channel and an additional second channel. The channels of the second pair of channels may communicate with each other via second overflow orifices.

A second slotted plate may be disposed between the channels of the second pair of channels.

The channels of the second pair of channels may be disposed one above the other (i.e., vertically displaced), and/or the second slotted plate may lie in a substantially horizontal plane.

The channels of the second pair of channels may be arranged such that a gas flow between the channels of the second pair of channels takes place in the vertical direction during operation.

The channels of the second pair of channels may be disposed offset in a horizontal direction in a side-by-side arrangement, and/or the second slotted plate may lie in a substantially vertical plane.

The channels of the second pair of channels may be arranged such that a gas flow between the channels of the second pair of channels takes place in the horizontal direction during operation.

At least one process module may comprise a plasma source, a gas supply device for supplying a plurality of process gases via separate gas distributors, and at least one gas extraction device for extracting the process gases. The plasma source may comprise, e.g., a magnetron, an inductively or a capacitively coupled source.

It is one aspect of the invention that the continuous machine may be configured as a platform for several pretreatment and coating processes, so that basic constructive elements such as the vacuum lock, the transport device, the configuration of the chambers, the control and automation are universally usable, whereas the type of the plasma sources and vacuum pumps are adapted to the specific use (e.g., magnetron sputtering or plasma-enhanced chemical vapor phase deposition (PECVD)).

A configuration in which at least one process module comprises a plasma source allows for a plasma-enhanced activation, e.g., for plasma-enhanced vapor phase deposition. The arrangement of the gas distributors improves the transfer rate of the substrates and/or reduces an undesired coating of plant components in the process region.

The at least one process module with the plasma source may comprise a first gas extraction device whose extraction orifice is disposed along a conveying direction of the substrates upstream the plasma source, and a second gas extraction device whose extraction orifice is disposed along the conveying direction downstream the plasma source. The arrangement of the extraction orifices reduces an unwanted coating, i.e., contamination of plant components in the process region.

The plasma source and the gas supply device may be combined in one component of the plant that is demountable from the continuous machine as a module. Maintenance times may be kept short by demounting the plasma source and the gas supply device as one component of the plant and replacing them with replacement components.

The continuous machine may further comprise a transport device for continuously transporting a sequence of substrate carriers through at least one section of the continuous machine, and a conveying module for conveying the substrate carrier between the vacuum lock and the transport device. The conveying module may be arranged between the vacuum lock and the process module or the process modules. The conveying module may buffer a substrate carrier, wherein the substrate carrier stays in the conveying module for a short time only. Alternatively or additionally, the conveying module may be configured for accelerating the substrate carrier downstream of an inlet vacuum lock and inserting it into a continuously moving sequence of substrate carriers and/or for separating the substrate carrier upstream of an outlet vacuum lock and removing it from the continuously moving sequence of substrate carriers. In order to separate the substrate carrier from the continuously moving sequence of substrate carriers, the substrate carrier may be accelerated first in order to increase a distance to the successive substrate carrier of the sequence of substrate carriers, and be slowed down afterwards.

The conveying module may comprise a temperature control device. The temperature control device may comprise a heating device for heating the substrates from both sides. After introduction of the substrates, a defined substrate temperature may be set by a controlled heating device before the substrates pass through the process line. On the other hand, the heating device allows for continuously compensating radiation losses of the substrates in the process line as well as maintaining good process conditions. The conveying module may be configured for cooling the substrates, particularly when it is arranged downstream of all the process modules.

The vacuum lock may be a vacuum lock for introducing the substrates.

The continuous machine may further comprise a second vacuum lock for removing the substrates. The second vacuum lock may comprise: a second chamber for receiving the substrate carrier and a second flow channel arrangement for evacuating and venting the second chamber, wherein the second flow channel arrangement comprises a third channel for evacuating and venting the second chamber and a fourth channel for evacuating and venting the second chamber, wherein the third channel and the fourth channel are disposed at opposing sides of the second chamber.

The use of two vacuum locks which are each vented and evacuated via a plurality of channels may allow for keeping low the operation times of the locks during both introduction and removal of the substrate carriers.

The continuous machine may further comprise a second conveying module for conveying the substrate carrier from the transport device to the discontinuously operating second vacuum lock.

The continuous machine may be configured for transporting the substrates between the first vacuum lock and the second vacuum lock through the continuous machine without interrupting a vacuum.

The continuous machine may comprise a plurality of process modules and at least one transfer chamber arranged between two process modules. The transfer chamber may serve for short-term buffering of substrate carriers between process modules and/or may guarantee a separation of process gases in different process modules.

The transfer chamber may be configured for conveying the substrates between the two process modules.

The continuous machine may be configured for introducing a nitrogen-containing first process gas and a silicon-containing second process gas into a process module with a plasma source via separate gas distributors. This makes possible the use of the plant for generating Sinₓ:H and, using a further, oxygen-containing process gas, also their suboxides or oxides such as, e.g., SiNₓO_{y}:H, a-SiₓO_{y}:H (i, n, p) and the like. Using hydrogen instead of a nitrogen-containing or oxygen-containing process gas allows for generating intrinsic, p- or n-doped a-Si:H (i, n, p) (amorphous, hydrogen-doped silicon) or nc-Si:H (i, n, p) or μc-Si:H (i, n, p) (nanocrystalline or microcrystalline, hydrogen-doped silicon). These thin layers may be used as passivation, doping, tunnel and/or antireflection coatings on semiconductor substrates.

The continuous machine may be a continuous machine, particularly a continuous vacuum plant, for producing solar cells. The continuous machine may particularly be a continuous machine for producing cells with passivated rear sides according to a PERX technology. PERX constitutes a family of cells with a passivated emitter and a passivated rear side, wherein X may stand, inter alia, for C (“PERC—Passivated Emitter and Rear Cell”), T (“PERT—Passivated Emitter and Rear Cell with Totally Diffused Back Surface Field”), L (“PERL—Passivated Emitter and Rear Cell with Locally Diffused Back Surface Field”) or other variations of PERC cells. Alternatively or additionally, the continuous machine may be used for producing heterojunction solar cells (HJT) or solar cells with passivated contacts such as, e.g., POLO or TopCON cells.

The continuous machine may be configured to coat both a first side (for instance, the front side) and a second side (for instance, the rear side) of the PERX solar cell in an inline configuration. In this way, PERX solar cells may be produced in a cost-effective and efficient way.

The continuous machine may be configured for introducing an oxygen-containing third process gas and an aluminum-containing fourth process gas into a further process module with an additional plasma source. This enables the use of the plant for producing multi-layer systems made of AlOₓ and SiNₓ:H sublayers for passivation, wherein the different layers may be deposited within the same continuous machine. The continuous machine is not limited to these multi-layer systems; any processes may be combined.

The continuous machine may be a continuous machine for applying an antireflection coating and/or passivation layer.

The vacuum lock may be configured such that a dynamic difference in pressure between the front and rear surfaces of the substrates or the front and rear surfaces of the substrate carrier is at most 10 Pa, preferably at most 5 Pa, particularly preferably at most 4 Pa, when a pressure change rate exceeds 100 hPa/s, preferably 300 hPa/s, while the chamber is being evacuated or vented.

The continuous machine may be a continuous machine for coating crystalline silicon wafers. The crystalline silicon wafers may be monocrystalline, multicrystalline or polycrystalline. However, the continuous machine is not limited to silicon wafers.

The continuous machine may be configured to process at least 4,000 substrates per hour, preferably at least 5,000 substrates per hour.

A cycle time of the continuous machine may be shorter than 60 s, preferably shorter than 50 s, further preferably shorter than 45 s. The cycle time of the continuous machine is the time in which a process, e.g., the introduction or removal of a substrate carrier at the vacuum lock, has been completed once and the vacuum lock is available again for the next process.

The cycle time is thus shorter than the throughput time of the continuous machine, which is the time required for running through the complete continuous machine from loading the loading lock until removal at the unloading lock.

An average transport velocity in the continuous machine and/or in the process module may be at least 25 mm/s, preferably at least 30 mm/s, further preferably at least 33 mm/s.

An average transport velocity in the continuous machine may depend on a throughput of the continuous machine. A throughput of at least 4,000 substrates per hour may take place at an average transport velocity of >25 mm/s. Preferably, an average transport velocity of 33 to 43 mm/s may be selected for a throughput of 5,000 to 6,000 substrates per hour.

A maximum velocity in the formation and dissolving of sequences of substrates within a conveying module may be considerably higher than the average transport velocity and is preferably <750 mm/s.

An operating time for evacuating the vacuum lock may be shorter than 25 s, preferably shorter than 20 s, further preferably shorter than 18 s. An operating time for venting the vacuum lock may be shorter than 16 s, preferably shorter than 10 s, further preferably shorter than 6 s.

The substrate carrier may be configured to receive at least 30, preferably at least 50, further preferably at least 64 substrates.

The vacuum lock may be configured such that a pumping time per substrate, which is determined as the pumping time of the vacuum lock divided by the complete number of substrates in the substrate carrier, and/or a venting time per substrate, which is determined as the venting time of the vacuum lock divided by the complete number of substrates in the substrate carrier, is shorter than 600 ms, preferably shorter than 500 ms and further preferably shorter than 400 ms.

At least one process module may comprise a sputter cathode.

According to a further aspect, a method for coating substrates in a continuous machine, particularly in a continuous vacuum plant, comprising a process module or a plurality of process modules is provided. The method comprises introducing the substrates into the continuous machine using a first vacuum lock. The method comprises processing the substrates in the process module or the process modules. The method comprises removing the substrates from the continuous machine using a second vacuum lock. At least one of the first and second vacuum locks comprises the following: a chamber for receiving a substrate carrier with substrates retained thereon, and a flow channel arrangement for evacuating and venting the chamber, wherein the flow channel arrangement comprises a first channel for evacuating and venting the chamber and a second channel for evacuating and venting the chamber, wherein the first channel and the second channel are disposed at opposing sides of the chamber.

The first vacuum lock and the second vacuum lock may both be configured such that a difference in pressure between front and rear surfaces of the substrates or front and rear substrate carrier surfaces of the substrate carrier is at most 10 Pa, preferably at most 5 Pa, particularly preferably 4 Pa, when a pressure change rate exceeds 100 hPa/s, preferably 300 hPa/s, while the chamber is being evacuated or vented.

The substrates may be crystalline silicon wafers.

The method may be used for producing solar cells. The method may particularly be used for producing one of the following solar cells: PERC (“Passivated Emitter Rear Cell”) cells, PERT (“Passivated Emitter and Rear Cell with Totally Diffused Back Surface Field”) cells, PERL (“Passivated Emitter and Rear Cell with Locally Diffused Back Surface Field”) cells, heterojunction solar cells, solar cells with passivated contacts.

The method may be carried out by the continuous machine according to the invention.

Additional features of the method, which may be implemented in exemplary embodiments, and the effects achieved therewith correspond to the optional features described with respect to the continuous machine.

The continuous machine and the method may be used for carrying out a plasma-enhanced chemical vapor phase deposition (PECVD) without being limited thereto. The PECVD may be carried out by means of an inductively coupled plasma source (ICP) without being limited thereto.

The continuous machine and the method may be used to treat substrates continuously during their transport through a plurality of process modules of the continuous machine.

The continuous machine and the method may be used to produce PERX silicon cells, to apply an antireflection coating, passivation coating or to carry out physical vapor phase deposition (PVD), to apply transparent, conductive coatings such as TCO, ITO, AZO, etc., to apply contacting layers, to apply all-over metal coatings (e.g., Ag, Al, Cu, NiV), or to apply barrier layers, without being limited thereto.

The continuous machines and methods according to the invention allow for short introduction and/or removal times for substrate carriers with substrates. High-quality layers or layer systems may be deposited on the substrates, wherein the productivity of the continuous machine may be increased at the same time. The costs for a coating per substrate may be kept low.

### BRIEF DESCRIPTION OF THE DRAWINGS

Exemplary embodiments of the invention are described in detail below with reference to the drawings in which identical reference signs designate identical or similar elements.

FIG. 1A is a schematic illustration of a continuous machine according to an exemplary embodiment in a top view.

FIG. 1B is a schematic illustration of a continuous machine according to an exemplary embodiment in a side view.

FIG. 1C is a schematic illustration of a continuous machine according to an exemplary embodiment in a side view.

FIG. 2 is a schematic illustration of a continuous machine according to an exemplary embodiment.

FIG. 3 is a schematic illustration of a continuous machine according to an exemplary embodiment.

FIG. 4 is a schematic illustration of a continuous machine according to an exemplary embodiment.

FIG. 5 is a schematic illustration of a continuous machine according to an exemplary embodiment.

FIG. 6 is a schematic illustration of a continuous machine according to an exemplary embodiment.

FIG. 7 shows a partial, perspective view of a vacuum lock of a continuous machine according to an exemplary embodiment.

FIG. 8 shows a partial, sectional view of the vacuum lock of FIG. 7.

FIG. 9 shows a sectional view of the vacuum lock of FIG. 7.

FIG. 10 shows a partially broken-away perspective view of the vacuum lock of FIG. 7.

FIG. 11 shows a diagram of the vacuum lock of a continuous machine according to an exemplary embodiment.

FIG. 12 shows a flow field at a first substrate carrier surface during evacuation of a chamber of the vacuum lock of a continuous machine according to an exemplary embodiment.

FIG. 13 shows a flow field at a second substrate carrier surface during evacuation of a chamber of the vacuum lock of a continuous machine according to an exemplary embodiment.

FIG. 14 shows a dynamic deposition rate of a SiNₓ:H layer on a monocrystalline silicon wafer as a function of the total gas flow of SiH₄ and NH₃.

FIG. 15 shows an average deposition rate of a SiNₓ:H layer on a monocrystalline silicon wafer as a function of the pressure for different gas flow rates.

FIG. 16 shows an absorption spectrum of a SiNₓ:H layer.

FIG. 17 shows reflection spectra of an individual SiNₓ:H antireflection layer and a SiN/SiNO double layer.

### DETAILED DESCRIPTION OF EXEMPLARY EMBODIMENTS

While preferred or advantageous exemplary embodiments are described with reference to the drawings, additional or alternative configurations may be implemented in further exemplary embodiments. While, for instance, a substrate carrier for essentially rectangular substrates is illustrated in the figures, continuous machines and methods according to the invention may also be used for non-rectangular substrates, e.g., circular substrates. While a chamber of a vacuum lock is evacuated and vented via channels provided at opposing face sides in exemplary embodiments illustrated in some of the figures, the channels may also be disposed at the longitudinal sides of the chamber of the vacuum lock in further exemplary embodiments.

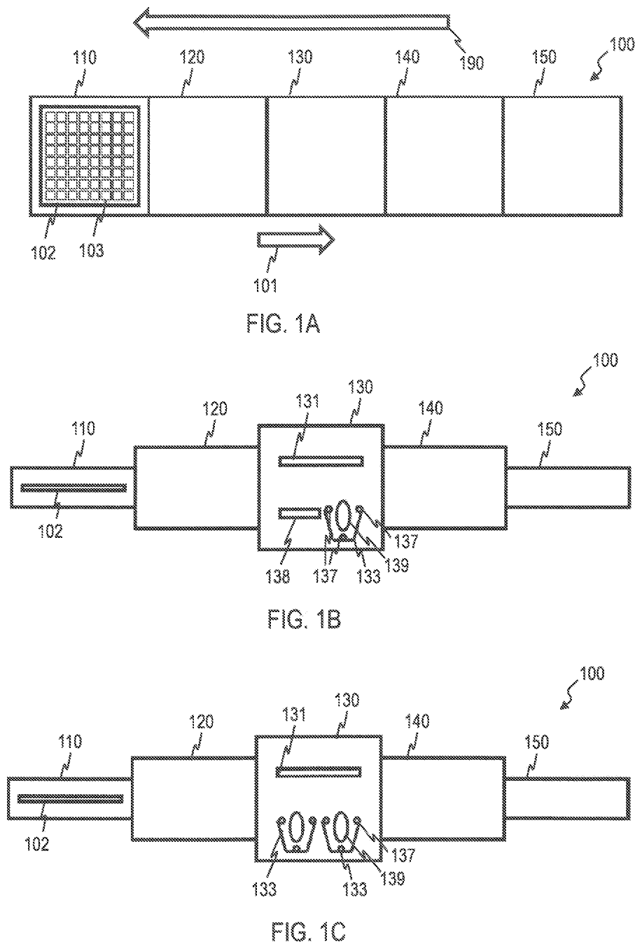

FIG. 1A shows a schematic illustration of a continuous machine 100 for treating substrates, particularly for coating substrates 103 in a top view. FIGS. 1B and 1C show schematic side views of exemplary embodiments of the continuous machine 100.

The continuous machine 100 comprises a substrate carrier 102 (which is also referred to as “carrier”) which may receive a plurality of substrates 103. The substrate carrier 102 may be configured to, e.g., receive at least 40, preferably at least 50, preferably at least 64 substrates.

The continuous machine 100 comprises a first vacuum lock 110 for introducing the substrate carrier 102 with the substrates 103. The continuous machine 100 comprises a first conveying module 120. The first conveying module 120 is configured to convey the substrate carrier from the discontinuously operating first vacuum lock 110 into a continuously transported sequence of substrate carriers at a transport device of the continuous machine 100. The first conveying module 120 may comprise components for accelerating the substrate carrier in order to convey it into the continuously transported sequence of substrate carriers. The first conveying module 120 may be configured such that the substrate carrier 102 may stay therein for a short time.

The continuous machine 100 comprises a process module 130. The process module 130 may be configured to coat the substrates 103 during a continuous transport through the process module 130. The process module 130 may be configured to carry out a plasma-enhanced chemical vapor phase deposition (PECVD). The process module 130 may be configured to apply an antireflection coating or a passivation layer. The process module 130 may be configured to carry out physical vapor phase deposition (PVD), to apply transparent, conductive coatings such as TCO, ITO, AZO, etc., to apply contacting layers, to apply all-over metal coatings (e.g., Ag, Al, Cu, NiV) or to apply barrier layers, without being limited thereto.

The process module may comprise at least one plasma source 133 and gas distributors 137 for different process gases. The gas distributors 137 may be formed integrally with the plasma source 133. The plasma source 133 may be an inductively coupled plasma source (ICP) or a capacitively coupled plasma source for generating a plasma 139 that is illustrated only schematically. The plasma source may comprise a sputter cathode. The plasma source 133 may comprise an alternating frequency generator or may be coupled to an alternating frequency generator.

The process module 130 may comprise a heating device 131, 138 in order to heat the substrates in the process module 130 from at least one side.

The process module 130 may comprise extraction orifices (not shown in FIG. 1) for aspirating reaction gases, wherein the extraction orifices are disposed, in a transport direction 101, upstream and downstream of the plasma source 133.

The plasma source 133 and the gas distributors 137 for different process gases may be configured as one component that is modularly exchangeable. The plasma source 133 and the gas distributors 137 may be demounted from the process module 130 as one component and replaced with an additional, identical component while the originally mounted plasma source 133 and the gas distributors 137 are being serviced.

Each of the gas distributors 137 may be arranged transversely to the transport direction 101. Each of the gas distributors 137 may comprise a tube with at least one outlet opening or with a plurality of openings for producing a defined gas distribution.

The use of the plasma source 133, which may particularly extend linearly transverse to the transport direction 101, and a supply of the process gases via separated gas distributors 137 in combination with extraction of the process gases upstream and downstream of the plasma source 133 may allow for good layer quality. The arrangement of the gas distributors 137 and extraction enhances the transfer rate of the substrates and/or reduces undesired coating of the components in the process area. By reducing the amount of unwanted coating, plant contamination is reduced. The reduced contamination allows for a longer production phase before maintenance is required for cleaning, particularly of the process areas. The plasma source 133 and the gas distributors 137 and gas supply device may be completely removed for maintenance purposes and replaced with a second plasma source and gas distributors that are integrally formed therewith. The configuration of the plasma source 133 and the replacement may shorten the time required for maintenance. The cleaning of the contaminated plasma source 133 may be carried out parallel to the operation of the continuous machine 130 so that an overhauled plasma source is available for the next maintenance.

Even if FIG. 1 illustrates one process module 130 only, the continuous machine 100 may comprise a plurality of process modules arranged consecutively along the transport direction. The plurality of process modules may be used for depositing different layers or layer systems and/or for coating first and second sides of the substrates.

The continuous machine 100 comprises a second conveying module 140. The second conveying module 140 is configured to convey the substrate carrier 102 from the continuously transported sequence of substrate carriers into a discontinuously operating second vacuum lock 150. The second conveying module 140 may comprise components for accelerating and stopping the substrate carrier 102 in order to separate it from the continuously transported sequence of substrate carriers and introduce it into the second vacuum lock 150.

The continuous machine 100 may comprise the second vacuum lock 150 for removing the substrate carrier 102 with the substrates 103.

The continuous machine 100 may comprise a returning device 190 for returning the substrate carrier 102 after removal of the substrates 103 for reusing the substrate carrier 102.

The first vacuum lock 110 and/or the second vacuum lock 150 may be configured such that a cycle time for a complete operating cycle is shorter than 60 s, preferably shorter than 50 s, particularly preferably shorter than 45 s. An operating time for evacuating the vacuum lock and/or an operating time for venting the vacuum lock may be shorter than 25 s, preferably shorter than 20 s, further preferably shorter than 18 s. In one embodiment, the operating time for evacuating the vacuum lock may be longer than the operating time for venting the vacuum locks. An operating time for evacuating the vacuum lock may be shorter than 25 s, preferably shorter than 20 s, further preferably shorter than 18 s. An operating time for venting the vacuum lock may be shorter than 16 s, preferably shorter than 10 s, further preferably shorter than 6 s.

In order to avoid accidental displacement of substrates 103 at the position within the substrate carrier 102 despite the short cycle time of the vacuum lock, the first vacuum lock 110 and/or the second vacuum lock 150 may be configured such that a difference in pressure between the front and rear surfaces of the substrates or the front and rear substrate carrier surfaces of the substrate carrier are at most 10 Pa, preferably at most 5 Pa, particularly preferably at most 4 Pa, when a pressure change rate exceeds 100 hPa/s, preferably 300 hPa/s, while the chamber is being evacuated or vented.

The first vacuum lock 110 and/or the second vacuum lock 150 may comprise a plurality of spaced apart channels for venting and evacuating a chamber of the corresponding vacuum lock 110, 150 in order to keep the time required for venting and evacuation short.

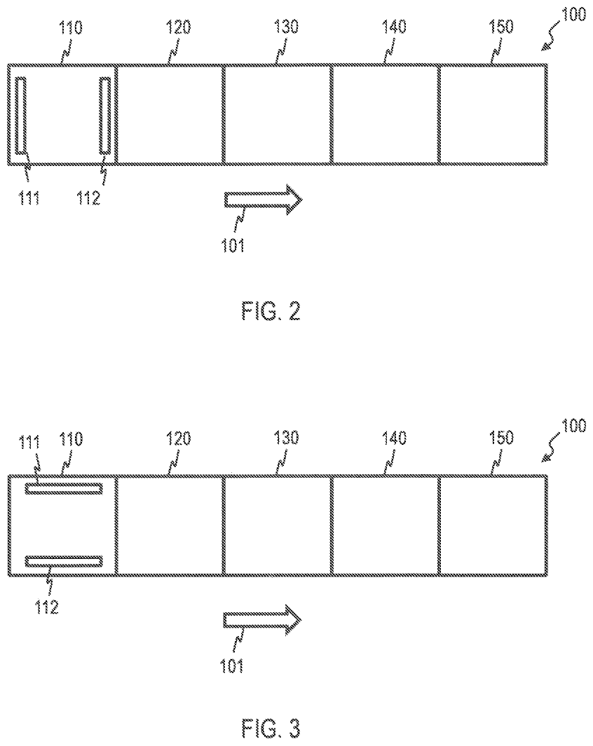

FIG. 2 and FIG. 3 show respective schematic top views of the continuous machine 100, wherein a first channel 111 and a second channel 112 are provided for venting and evacuating the chamber of the first vacuum lock 110. The first channel 111 and the second channel 112 may be disposed at opposing face sides of the first vacuum lock 110 transversely to the transport direction 101 of the continuous machine 100, as illustrated by FIG. 2. The first channel 111 and the second channel 112 may be disposed at opposing longitudinal sides of the first vacuum lock 110 parallel to the transport direction 101 of the continuous machine 100, as illustrated by FIG. 3.

Even though channels 111, 112 are illustrated for the first vacuum lock 110, the second vacuum lock 150 may alternatively or additionally comprise a corresponding arrangement of a plurality of channels for venting and evacuating the chamber of the second vacuum lock 150.

The continuous machine 100 may be configured to transport the substrate carrier 102 with the substrates 103 in horizontal orientation through the continuous machine. Heating devices may be provided in one or a plurality of the first conveying modules 120 and the process module 130. The heating devices may be configured to heat the substrates 103 from both their upper sides and their lower sides. Both the conveying module 120 and the process module 130 may comprise a first heating device arranged above the transport plane of the substrate carrier 102 and a second heating device arranged below the transport plane of the substrate carrier 102.

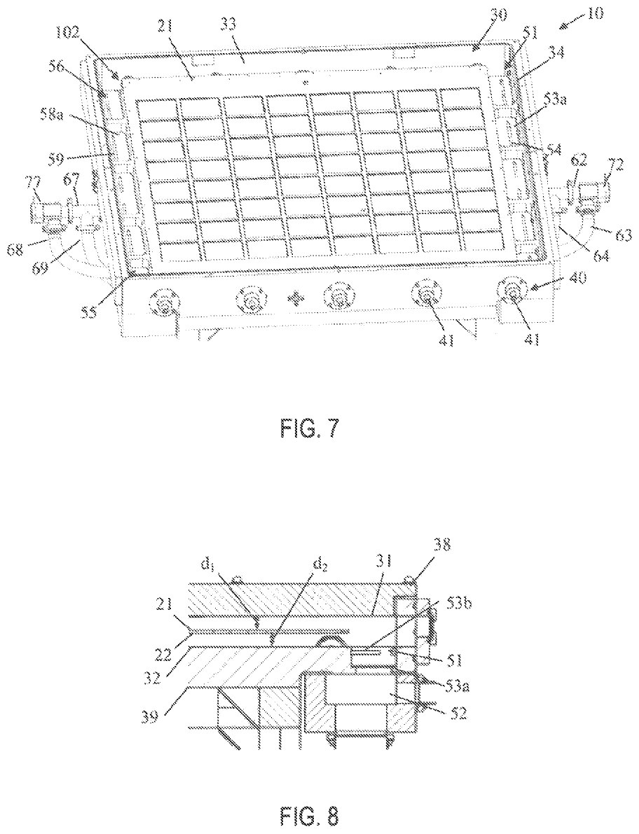

The throughput of the continuous machine is determined by the number of plasma sources and the width of the plasma sources. The number of required plasma sources may be kept low by a high coating rate and a high transfer rate. The introduction and/or removal of the substrates is achieved with short cycle times by the configuration of the vacuum locks 110 and/or 150, which is described in more detail with respect to FIGS. 7 to 13. The combination of a plasma source with a high transfer rate and quick introduction/removal of the substrates allows for high throughput.

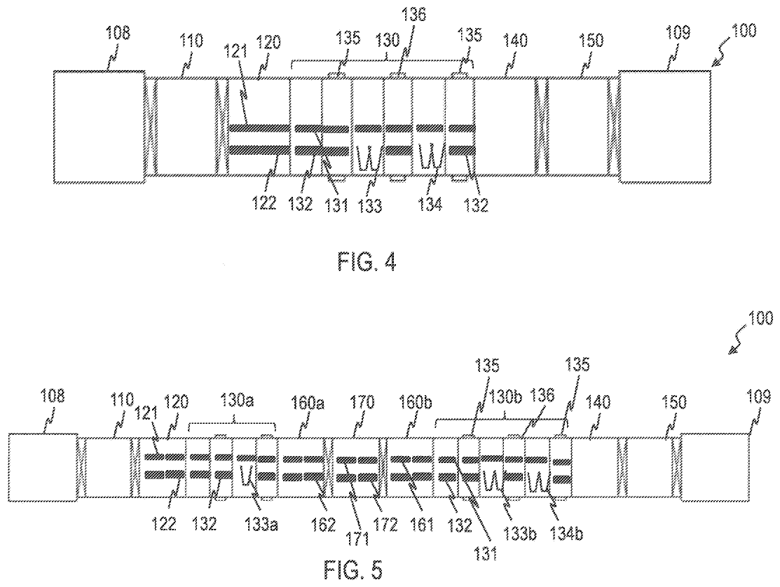

FIG. 4 is a schematic side view of a continuous machine 100 according to an exemplary embodiment, which is configured for applying a passivation/antireflection coating. The continuous machine comprises a first vacuum lock 110, a first conveying module 120, a process module 130, a second conveying module 140 and a second vacuum lock 150, which may comprise the embodiment and operating mode described with respect to FIG. 1 to FIG. 3.

Both the first conveying module 120 and the process module 130 comprise heating devices 121, 122, 131, 132. The heating devices 121, 122 of the conveying module 120 may be configured to heat the substrates 103 in the conveying module 120 from at least one and preferably from both sides. The heating devices 131, 132 of the process module 130 may be configured to heat the substrates 103 in the process module 130 from at least one and preferably from both sides. The second conveying module 140 may optionally comprise devices for cooling the substrates (not shown).

Substrates 103 may be inserted into the substrate carrier 102 by an optional, automated loading device 108. Alternatively or additionally, coated substrates may be removed from the substrate carrier 102 by an optional, automated unloading device 109.

The process module 130 comprises plasma sources 133, 134 with gas distributors for different process gases. Each of the separate gas distributors of the plasma sources 133, 134 may introduce, e.g., a nitrogen-containing first process gas (e.g., NH₃) into the region of the plasma zone via a gas inlet, wherein the process gas is then activated therein by the plasma source. Separated from the first process gas, a silicon-containing process gas (e.g., SiH₄) may be introduced in the vicinity of the substrate surface and the transport device and remote from the plasma generation site. The extraction of the gases may take place between the transport device and the second gas inlet, e.g., at extraction ports 135. In order to deposit a silicon nitride layer having a layer thickness of at least 50 nm, at least one inductively coupled plasma source (ICP source) may be present within the process module 130.

Optionally, the process module 130 may comprise, between the plurality of plasma sources 133, 134, an intermediate region 136 in which no plasma is produced but rather the substrate 103 is heated from both sides by heating devices. In additional embodiments, the intermediate region 136 may be omitted as well.

The intermediate region 136 may optionally comprise one or a plurality of extraction ports. The extraction ports 135, 136 may be connected to a vacuum generation device (not shown) for generating the desired process pressure.

In the process area, a reaction gas may generally be introduced via a gas inlet into the region of the plasma zone and activated there. Separated therefrom, the layer forming agent/precursor may be introduced as a gas separately from the first gas in the vicinity of the substrate surface and the transport device and away from the plasma production site.

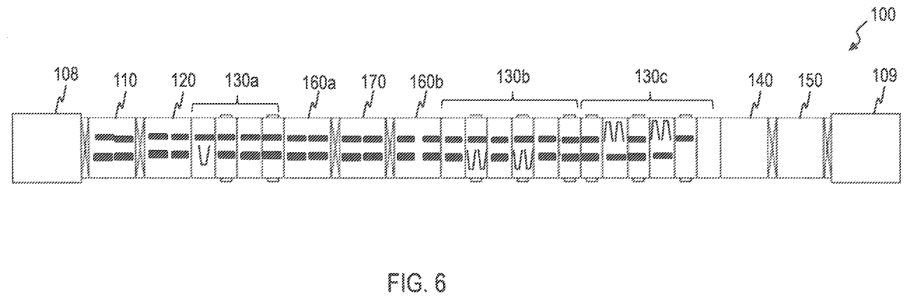

A plurality of process modules may be combined in order to coat the substrates with more complex layer systems and/or both at the first and the second side, as is described in more detail with respect to FIG. 5 and FIG. 6.

FIG. 5 is a schematic side view of a continuous machine 100 according to an exemplary embodiment, which is configured to apply a passivation layer and an antireflection coating at a second side (e.g., a rear side) of a silicon wafer. The continuous machine comprises a first vacuum lock 110, a first conveying module 120, a first process module 130a, a second process module 130b, a second conveying module 140 and a second vacuum lock 150, which may have the configuration and operation described with reference to FIG. 1 to FIG. 4.

Substrates 103 may be inserted into the substrate carrier 102 by an optional, automated loading device 108. Alternatively or additionally, coated substrates may be removed from the substrate carrier 102 by an optional, automated unloading device 109.

Between the first process module 130a and the second process module 130b, a transfer chamber 170 is provided, which guarantees gas separation between the first process module and 130a and the second process module 130b. The transfer chamber 170 may transfer the substrate carrier 102 with the substrates 103 retained thereon between the first process module 130a and the second process module 130b.

Conveying modules 160a, 160b may convey the substrate carrier 102 between a continuously transported sequence of substrate carriers and the discontinuously operating transfer chamber 170. In doing so, the conveying module 160a may operate similar to the second conveying module 150 and take over the substrate carrier 102 from the transport device, separate it from the sequence of substrate carriers and convey it into the transfer module 170. In order to separate the substrate carrier 102 from the sequence of substrate carriers, the substrate carrier 102 may be accelerated in the conveying module first and be slowed down thereafter. The conveying module 160b may operate similar to the first conveying module 120 and take over the substrate carrier 102 from the transfer module 170, accelerate it and insert it into the sequence of continuously transported substrate carriers.

The first conveying module 120, the process modules 130a, 130b, the conveying modules 160a, 160b and the transfer chamber 170 may comprise heating devices 121, 122, 131, 132, 161, 162, 171, 172. The heating devices 121, 122 of the conveying module 120 may be configured to heat the substrates 103 in the first conveying module 120 from at least one and preferably from both sides. The heating devices 131, 132 of the process modules 130a, 130b may be configured to heat the substrates 103 in the process modules 130a, 130b from at least one and preferably from both sides. Corresponding heating devices may be present in the conveying modules 160a, 160b and the transfer chamber 170. The second conveying module 140 may optionally comprise a device for cooling the substrates.

The first process module 130a may be configured to apply a passivation layer. The first process module 130a may be configured to deposit an aluminum oxide sublayer. For this purpose, an oxygen-containing gas (e.g., O₂, N₂O) may be introduced via a gas inlet into the region of the plasma zone and activated there. Separated therefrom, an aluminum-containing gas (e.g., trimethylene aluminum (TMAI)) is introduced in the vicinity of the substrate surface and the transport device and remote from the plasma generation site. The extraction of the gases may take place between the transport device and the second gas distributor. In order to deposit an aluminum oxide layer having a layer thickness of at least 10 nm, at least one ICP source may be present in the first process module 130a.

The second process module 130b may be configured to apply an antireflection coating. The second process module 130b comprises plasma sources 133b, 134b with gas distributors for different process gases. Via the gas distributors of the plasma sources 133b, 134b, e.g., a nitrogen-containing first process gas (e.g., NH₃) may be introduced via a gas inlet into the region of the plasma zone and be activated there by the plasma source. Separated from the first process gas, a silicon-containing process gas (e.g., SiH₄) may be introduced in the vicinity of the substrate surface and the transport device and remote from the plasma generation site. The gases may be extracted between the transport device and the second gas inlet, e.g., at extraction ports 135. In order to deposit a silicon nitride layer having a layer thickness of at least 50 nm, at least one additional, inductively coupled plasma source (IPC source) may be present in the second process module 130b.

FIG. 6 is a schematic side view of a continuous machine 100 according to an exemplary embodiment, which is configured for applying a passivation layer and an antireflection coating at a second side of a silicon wafer as well as additionally for applying an antireflection coating at a first side of the silicon wafer.

The continuous machine 100 comprises a first vacuum lock 110, a first conveying module 120, a first process module 130a, a transfer module 170 and conveying modules 160a, 160b, a second process module 130b, a second conveying module 140 and a second vacuum lock 150, which may have a configuration and operation as described with respect to FIG. 1 to FIG. 5. Substrates 103 may be inserted into the substrate carrier 102 by an optional, automated loading device 108. Alternatively or additionally, coated substrates may be removed from the substrate carrier 102 by an optional, automated unloading device 109.

The continuous machine 100 further comprises a third process module 130c which is configured for applying an antireflection coating at the first side of the silicon wafer.

The third process module 130c comprises one or a plurality of plasma sources with gas distributors for different process gases. Via a gas distributor, a nitrogen-containing first process gas (e.g., NH₃) may be introduced via a gas inlet into the region of the plasma zone and be activated there by the plasma source. Separated from the first process gas, a silicon-containing process gas (e.g., SiH₄) may be introduced in the vicinity of the substrate surface and the transport device and remote from the plasma generation site. The gases may be extracted between the transport device and the second gas inlet. At least one ICP source may be present in the third process module 130c in order to deposit a silicon nitride layer with a layer thickness of at least 50 nm on the first side of the silicon wafer.

In the third process module 130c, the ICP source and the gas distributors are arranged at a side relative to the transport plane different from that in the second process module 130b. For instance, the ICP source may be disposed below the transport plane of the substrate carrier in the second process module 130b and above the transport plane of the substrate carrier in the third process module 130c.

The operation of the continuous machine during the application of a layer system of a passivation layer and an antireflection coating—as may be carried out, e.g., with the continuous machines of FIG. 5 and FIG. 6—will be described below.

In order to coat the rear sides of semiconductor wafers with AlOₓ and SiN for producing solar cells, the continuous machine may comprise at least one process module 130a, 130b which is configured as a plasma chamber for plasma-enhanced chemical vapor phase deposition (PECVD). The plasma chamber comprises at least one device for generating a plasma. The plasma chamber may comprise a gas supply device, a vacuum system and a transport device. The transport device may be configured for the horizontal transport of substrate carriers with substrates along the continuous machine.

The substrates 103 are introduced on the substrate carrier 102 via the first vacuum lock 110. In the first vacuum lock 110, the pressure is reduced from atmospheric pressure to a pressure that is smaller than 10 kPa, preferably smaller than 1 kPa, particularly preferably smaller than 100 Pa, before the substrates in the substrate carrier enter the process module 130a, 130b.

The substrate carrier 102 with the substrates 103 is conveyed from the first vacuum lock 110 into the first conveying module 120, which may serve for short-term buffering. The temperature in the first conveying module 120 may be controlled. Preferably, the substrates 103 are heated. Temperature control may take place by controlling an optionally present heating device of the conveying module 120. The transition from a discontinuous to a continuous transport of the substrate carriers 102 takes place within the conveying module 120 by forming a continuous sequence of substrate carriers.

The transport device of the continuous machine may facilitate adjustment of a distance between two successive substrate carriers to a defined range. For this purpose, the subsequent substrate carrier must be accelerated first, and its velocity must be adjusted when reaching the velocity of the substrate carrier running in front of it. This may take place in the conveying module 120.

The sequence of substrate carriers runs through the process area at a defined velocity of the transport device.

In order to improve the quality of the layers as well as operational safety, and to reduce hazard sources, it may be advantageous to separate different process areas by a transfer chamber 170. The different regions may be separated from each other by slit valves/sliders. The transfer chamber 170 prevents the process gases from mixing between the process areas during the transport of the substrates. Prior to the transfer into the next process area, the parameters in the transfer chamber 170 (e.g., the pressure) are adjusted.

The continuous sequence of substrate carriers is suspended in front of the transfer chamber 170 in the conveying module 160a and in front of the second vacuum lock 150 in the second conveying module 140 so that individual substrate carriers may be conveyed from one process area into the next or into the second vacuum lock 150.

In the second vacuum lock 150, the substrate carriers with the substrates from the continuous machine 100 are transferred to atmospheric pressure. The temperature in the second conveying module 140 after the last process area and in front of the second vacuum lock 150 may be controlled. In particular, the temperature of the substrate carrier and the substrates may be reduced prior to their leaving the continuous machine. Particularly preferably, the second conveying module 140 is configured to cool the substrate carriers and substrates.

In the process area of the process modules 130a, 130b, a reaction gas may be introduced via a gas inlet into the region of the plasma zone and activated there. Separately from the first gas, the layer-forming agent/precursor may be introduced as a gas in the vicinity of the substrate surface or the transport device and remote from the plasma generation site. The extraction of the gases takes place between the transport device and the second gas inlet. After running through the continuous machine 100 according to FIG. 5 and FIG. 6, the substrates comprise a layer system consisting of sublayers of aluminum oxide and silicon nitride.

The substrates coated with an aluminum oxide layer comprise a satisfactory layer distribution, a satisfactory quality and a satisfactory lifetime. The quality and the lifetime of the substrates coated with aluminum oxides depend on the refractive index and the density or porosity of the deposited thin layer. The choice of plasma generation and suitable process parameters (pressure, gas flows, temperature, plasma output, etc.) in combination with the plant's geometry allow the required characteristics of the layers to be attained.

Plasma sources with capacitive and inductive excitation of plasma may be used for plasma generation in the continuous machines according to FIG. 1 to FIG. 6. A linear ICP source with at least one excitation frequency ranging from 13 MHz to 100 MHz is particularly preferred. The ICP source serves for producing plasma at a length of >1,000 mm, preferably of >1,500 mm, particularly preferably of >1,700 mm. The RF generators may have a power of >4 kW, preferably of >6 kW, particularly preferably of >7 to 30 kW and very particularly preferably of 8 to 16 kW. The RF generator may be operated in a pulsed manner.

In the continuous machines 100, the substrates may be transported from the first vacuum lock 110 to the second vacuum lock 150 without interrupting the vacuum.

The continuous machines 100 may allow for the production of a homogeneous aluminum oxide layer with low porosity and good control over the refractive index n.

The continuous machines 100 may allow for an efficient coating of substrates, particularly silicon wafers, which may be monocrystalline, multicrystalline, or polycrystalline silicon wafers, without being limited thereto.

The continuous machines 100 may be configured for aspirating the reaction products with vacuum pumps in the process areas. Preferably, separated vacuum systems may be provided for the process module 130a to deposit aluminum oxides and for the process module 130b or the process modules 130b, 130c to deposit silicon nitride.

The continuous machines 100 may be configured to minimize the time in which the reaction products stay in the process area so that they are not integrated into the coating. For this purpose, an active extraction of the reaction products may be provided.

The continuous machines 100 may be configured for a uniform extraction of the reaction products transversely to the transport direction 101 in order to create equal conditions across the coating width.

The continuous machines 100 may be configured such that the flow direction of the precursor is controlled with respect to the substrate plane and the excitation of the plasma. This may be achieved by a suitable geometry of the gas distributor.

The continuous machines 100 may comprise different arrangements of the plasma sources with respect to the transport plane. The continuous machine may comprise a first plasma source disposed above the transport plane for coating a first substrate side, and a second plasma source disposed below the transport plane for coating a second substrate side opposing the first substrate side.

A process module 130a, 130b, 130c of the continuous machine may comprise a plurality of plasma sources.

The transfer chamber 170 may comprise its own vacuum system.

In order to address the conflict between a high coating rate and a high layer quality, the continuous machine 100 may be configured to produce a plurality of thin layers (sublayers) instead of one individual thick layer. The requirements with regard to functionality may be distributed to the sublayers. For instance, an antireflection coating with good passivation may be deposited at the boundary surface between the substrate and the layer, and another optical layer may be deposited in order to form a two-layer system.

One and the same type of plasma source may be used for different processes and different process modules.

A separate gas supply of the plasma sources allows for a higher variation of the layer properties at adjacent plasma sources 133/134 or 133a/133b since the gas composition may be varied.

By aspirating gases between the plasma sources, adjacent plasma sources may be decoupled in a better way.

In any of the described continuous machines 100, the optional heating devices may comprise infrared radiators and/or resistance heaters. The heating devices may be controlled in order to set the substrate temperature.

In order to achieve a short process time per substrate, the first vacuum lock 110 and/or the second vacuum lock 150 may be configured such that a short operating time of the vacuum lock may be achieved. Exemplary embodiments of a vacuum lock 10, which may be used as the first vacuum lock 110 and/or the second vacuum lock 150, are described with respect to FIG. 7 to FIG. 13.

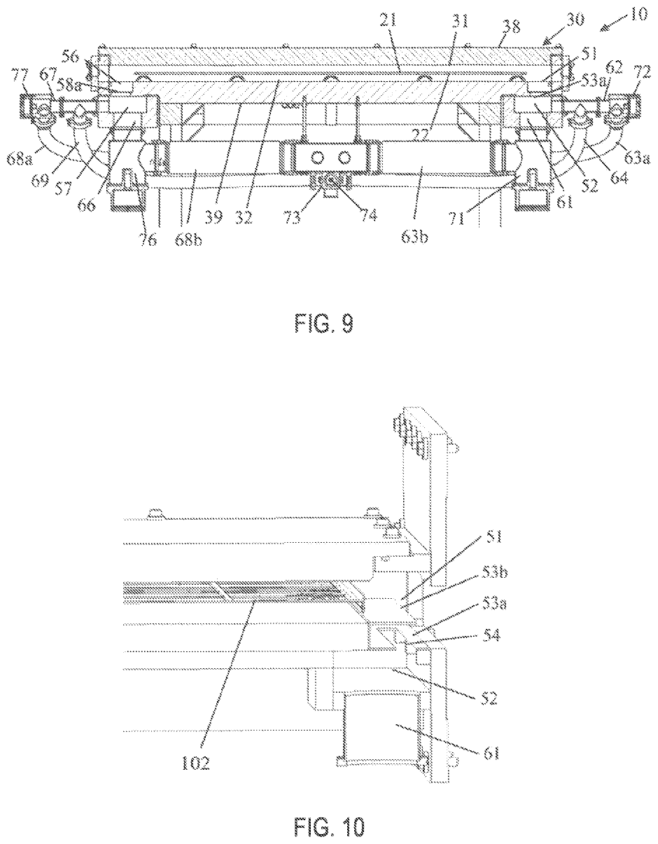

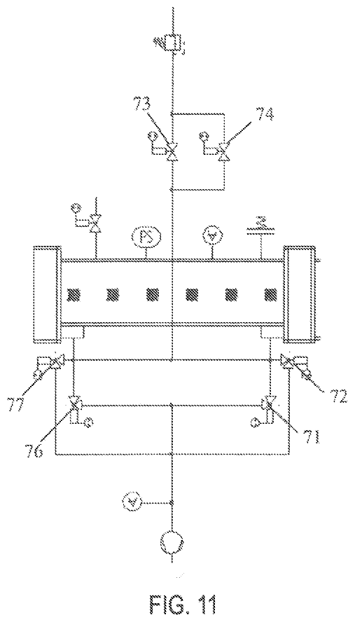

FIG. 7 shows a partial, perspective view of a vacuum lock 10, wherein an upper chamber part 38 of a chamber 30 of the vacuum lock 10 is not illustrated. FIG. 8 shows a partial, sectional view of an end region of a chamber 30 of the vacuum lock 10. FIG. 9 shows a sectional view of the chamber 30. FIG. 10 shows a partially broken-away perspective view of the chamber 30.

The chamber 30 is configured for receiving a substrate carrier 102. The substrate carrier 102 comprises a plurality of receptacles for substrates. In this context, the substrates may be positioned at the substrate carrier 102 such that pressure compensation is substantially eliminated by the openings present in the substrate carrier 102 when the substrates are positioned at or within the substrate carrier 102.

The chamber 30 comprises an upper chamber part 38 and a lower chamber part 39. The upper chamber part 38 comprises a first inner surface 31 which faces towards the substrate carrier 102 during the transfer of substrates. The lower chamber part 39 comprises a second inner surface 32 which faces towards the substrate carrier 102 during the transfer of substrates. The first inner surface 31 and the second inner surface 32 are advantageously substantially flat. The substrate carrier 102 comprises a first substrate carrier surface 21 which faces towards the first inner surface 31 during transfer of the substrates. The substrate carrier 102 comprises a second substrate carrier surface 22 which faces towards the second inner surface 32 during the transfer of the substrates.

The chamber 30 comprises an internal volume. The internal volume of the chamber 30 may be at least 100 l, preferably from 200 to 500 l.

The vacuum lock 10 may comprise a transport device 40. The transport device 40 comprises drive components 41 for transporting the substrate carrier. The drive components 41 are configured to move the substrate carrier 102 in a travel direction. The drive components 41 may be a plurality of feed rollers which are spaced apart from each other along the travel direction at the chamber 30. The substrate carrier 102 may rest on the drive components 41.

The axes of the drive components may be located below the chamber bottom in the vacuum lock. Preferably, the axes within the lock are partially embedded into the chamber bottom in order to minimize the volume of the chamber of the vacuum lock.

As illustrated in FIG. 8 and FIG. 9, the conveyor 40 is configured to position the substrate carrier 102 between the first inner surface 31 and the second inner surface 32 of the chamber 30.

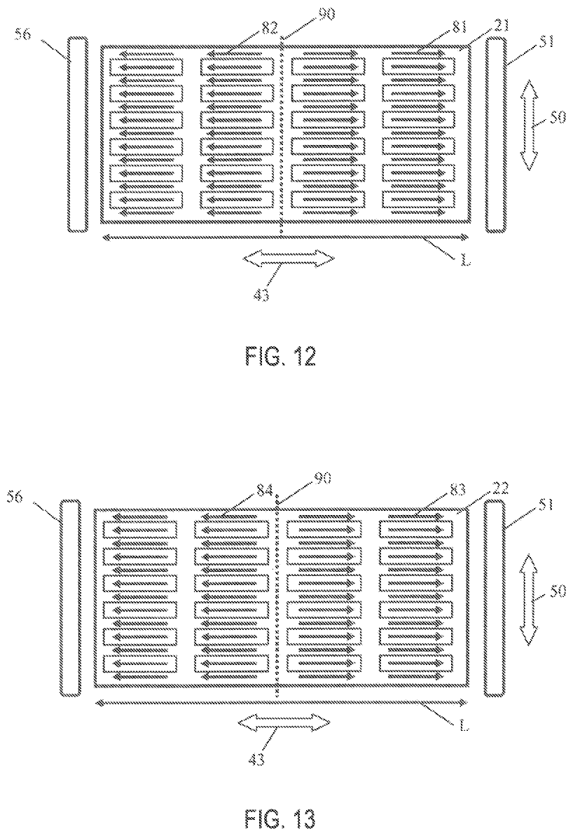

The vacuum lock 10 may be configured such that static differences in pressure between the first substrate carrier surface 21 and the second substrate carrier surface 22 are kept small during venting and/or evacuation, e.g., smaller than 10 Pa, preferably smaller than 5 Pa, further preferably smaller than 4 Pa, while the chamber is being vented or evacuated. For this purpose, different measures may be taken:
The vacuum lock 10 is vented or evacuated by a plurality of channels.
The conveyor 40 may position the substrate carrier 102 such that the distances of the substrates in the substrate carrier 102 to the first inner surface 31 and to the second inner surface 32 of the chamber are substantially the same.
A ratio of a distance between an inner surface of the chamber and the opposing substrate carrier surface to a length L of the substrate carrier (illustrated in FIG. 12 and FIG. 13) is smaller than 0.1, preferably smaller than 0.05, further preferably smaller than 0.025. This advantageously applies to both the ratio of a first distance di between the first inner surface 31 and the first substrate carrier surface 21 to the length L and to a ratio of a second distance d₂ between the second inner surface 32 and the second substrate carrier surface 22 to the length L of the substrate carrier 102.
In the travel direction of the substrate carrier 102 defined by the conveyor 40, the gas may be introduced and/or evacuated along the travel direction and opposite the travel direction so that the gas flows in different directions at both halves of the substrate carrier 102, as illustrated in FIG. 12 and FIG. 13.
The vacuum lock 10 may comprise a flow channel arrangement which is configured to enable a substantially homogeneous gas flow transversely to the travel direction of the substrate carrier. By means of the flow channel arrangement, e.g., diagonal gas flows over the substrate carrier surfaces 21, 22 may be prevented.

By way of the aforementioned as well as optional further measures, it may be achieved that, at two points at the first substrate carrier surface 21 and the second substrate carrier surface 22 that are vertically spaced apart, the velocities of the gas flow are all substantially the same during evacuation of the chamber 30. Moreover, the velocities of the gas flow may all be substantially the same at two points at the first substrate carrier surface 21 and the second substrate carrier surface 22 that are vertically spaced apart during venting of the chamber 30. A flow resistance with respect to the gas flow in the region between the first substrate carrier surface 21 and the first inner surface 31 as well as a flow resistance with respect to the gas flow in the region between the second substrate carrier surface 22 and the second inner surface 32 may be substantially the same if the substrate carrier 102 is positioned symmetrically between the first inner surface 31 and the second inner surface 32 in order to minimize dynamic and static differences in pressure between the first substrate carrier surface 21 and the second substrate carrier surface 22. For instance, a ratio of a first flow resistance between the substrate carrier 102 and the first inner surface 31 to a second flow resistance between the substrate carrier 102 and the second inner surface 32 may lie within a range of between 0.95 and 1.05 and preferably of between 0.97 and 1.03.

By way of an embodiment in which the ratio of the first distance d₁ between the first inner surface 31 and the first substrate carrier surface 21 to the length L of the substrate carrier as well as the ratio of a second distance d₂ between the second inner surface 32 and the second substrate carrier surface 22 to a length L of the substrate carrier 102 is smaller than 0.1, preferably smaller than 0.05 and particularly smaller than 0.025, and in which the distances d₁ and d₂ are similar, flat interior volumes may be formed within the chamber between the substrate carrier and the inner walls of the chamber, which may be vented and/or evacuated quickly. Differences in pressure between the upper and lower sides of the substrate carrier may be kept small.

In particular, in case the chamber is vented and/or evacuated at two opposing sides, the ratio of the first distance d₁ to half the length of the substrate carrier may be smaller than 0.1, preferably smaller than 0.05, i.e., d₁/(L/2)<0.1, preferably d₁/(L/2)<0.05, and the ratio of the second distance d₂ to half the length of the substrate carrier may be smaller than 0.1, preferably smaller than 0.05, i.e., d₂/(L/2)<0.1, preferably d₂/(L/2)<0.05.

The substrate carrier 102 resting horizontally on the conveyor 40 may have an area of more than 1 m², particularly of more than 2 m², e.g., of at least 2.25 m². Both the first substrate carrier surface 21 and the second substrate carrier 22 may be configured so as to be flat. The substrate carrier 102 may be positioned between the first inner surface 31 and the second inner surface 32 of the chamber such that a relative difference of a first distance d₁ between the first substrate carrier surface 21 and the first inner surface 31 and of a second distance d₂ between the second substrate carrier surface 22 and the second inner surface 32 is less than 15%, preferably less than 8%, i.e., that |d₁−d₂|/max(d₁, d₂)<15%, and particularly that |d₁−d₂|/max(d₁, d₂)<8%. By means of the substantially symmetric positioning of the substrate carrier 102 within the chamber 30, the gas flow at the upper and lower sides of the substrate carrier 102 generated during venting or evacuation is the same. Thus, differences in pressure between the first substrate carrier surface 21 and the second substrate carrier surface 22 are prevented.

The vacuum lock 30 comprises a flow channel arrangement 51, 52, 56, 57 for evacuating and venting the chamber 30. The flow channel arrangement may comprise a first channel 51 via which the chamber 30 may be both vented and evacuated. The first channel 51 may be disposed at a face side of the chamber 30 via which the substrate carrier 102 is inserted into the chamber 30 or withdrawn from the chamber 30. The first channel 51 may extend transversely to the travel direction of the substrate carrier 102. In another embodiment, the first channel 51 may be arranged at a longitudinal side of the chamber 30 and extend parallel to the travel direction of the substrate carrier 102.

A second channel 56 may be disposed opposite the first channel 51. The second channel 56 may allow for both venting and evacuation of the chamber 30. During operation, the chamber 30 may be evacuated both via the first channel 51 and the second channel 56 at the same time. During operation, the chamber 30 may be vented both via the first channel 51 and the second channel 56 at the same time. By way of a simultaneous venting or evacuation at opposing sides of the chamber 30, the maximum gas volume flowing over the substrate carrier 102 is divided in halves.

The first channel 51 and the second channel 56 are arranged such that the substrate carrier 102 and the substrates positioned thereat do not overlap the first channel 51 and the second channel 56 in a top view during venting and/or evacuation. Differences in pressure between the first substrate carrier surface 21 and the second substrate carrier surface 22 may thus be avoided. The first channel 51 and the second channel 56 are both advantageously dimensioned such that no significant pressure gradient is created in the vertical direction. In this way, it is ensured that an identical pumping capacity and venting capacity is achieved at the upper and lower sides of the substrate carrier 102.

In order to reduce static pressure gradients during evacuation and venting of the chamber 30, e.g., more complex flow channel assemblies may be used. An additional first channel 52 may be arranged below the first channel 51. The additional first channel 52 may communicate with the first channel 51 via one or a plurality of overflow orifices 54. All of the overflow orifices 54 may be configured as slots. In a top view, an area of the one or the plurality of overflow orifices 54 may be smaller, particularly much smaller than an area of the additional first channel 52 in a horizontal section plane. The overflow orifice 54 between the first channel 51 and the additional first channel 52 may be disposed and dimensioned such that an overflow of the gas between the first channel 51 and the additional first channel 52 takes place that is uniform along a longitudinal direction of the first channel 51. Thus, the first channel 51 may serve as an upper equalization channel and the additional first channel 52 may serve as a lower equalization channel. In combination, the first channel 51 and the additional first channel 52 may bring about a pressure compensation in such a way that no significant change in hydrostatic pressure arises along the longitudinal direction of the first channel 51 during evacuation or venting, and that no significant change in hydrostatic pressure arises along the height of the first channel 51 during evacuation or venting.

The first channel 51 and the additional first channel 52 may be disposed one above the other, i.e., vertically displaced. In this context, the overflow orifices allow for a fluid flow in the vertical direction between the first channel 51 and the additional first channel 52.

A slotted plate 53a between the first channel 51 and the additional first channel 52 may lie in a substantially horizontal plane.

In another exemplary embodiment, the first channel 51 and the additional first channel 52 may be arranged next to each other displaced in the horizontal direction. In this case, the overflow orifices 54 between the first channel 51 and the additional first channel 52 allow for a fluid flow in the horizontal direction.

If the overflow orifices are provided in a slotted plate, the slotted plate may lie in a substantially vertical plane.

The first channel 51 and the additional first channel 52 may thus serve as two equalization channels that are arranged next to one another. The first channel 51 and the additional first channel 52 may, in combination, bring about a pressure compensation to the effect that no significant change in hydrostatic pressure arises along the longitudinal direction of the first channel 51 during evacuation or venting, and that no significant change in hydrostatic pressure arises along the height of the first channel 51 during evacuation or venting.

The flow channel arrangement may be configured symmetrically, particularly mirror-symmetrically to a center plane 90 of the chamber 30. An additional second channel 57 may be arranged below the second channel 56. The additional second channel 57 may communicate with the second channel 56 via one or a plurality of overflow orifices. Any of the additional overflow orifices may be configured as slots in a slotted plate 58a. An additional baffle plate (not shown) for deflecting the gas flow may at least partially overlap the additional overflow orifices. The additional overflow orifices between the second channel 56 and the additional second channel 57 are arranged and dimensioned such that an overflow of the gas between the second channel 56 and the additional second channel 57 takes place that is uniform along the longitudinal direction of the second channel 56. The second channel 56 may thus serve as an upper equalization channel, and the additional second channel 57 may serve as a lower equalization channel. The second channel 56 and the additional second channel 57 may, in combination, bring about a pressure compensation to the effect that no significant change in hydrostatic pressure arises along the longitudinal direction of the second channel 56 during evacuation or venting, and that no significant change in hydrostatic pressure arises along the height of the second channel 56 during evacuation or venting.

The second channel 56 and the additional second channel 57 may be arranged one above the other, i.e., vertically displaced. In this context, the overflow orifices allow for a fluid flow in the vertical direction between the second channel 56 and the additional second channel 57.

The slotted plate 58a between the second channel 56 and the additional second channel 57 may lie in a substantially horizontal plane.

In another exemplary embodiment, the second channel 56 and the additional second channel 57 may be arranged next to each other displaced in the horizontal direction. The overflow orifices between the second channel 56 and the additional second channel 57 thus allow for a fluid flow in the horizontal direction.

In case the overflow orifices are provided in the slotted plate 58a, the slotted plate may lie in a substantially vertical plane.

The second channel 56 and the additional second channel 57 may thus serve as two equalization channels that are arranged next to one another. The second channel 56 and the additional second channel 57 may, in combination, cause a pressure compensation to the effect that no significant change in hydrostatic pressure arises along the longitudinal direction of the second channel 56 during evacuation or venting, and that no significant change in hydrostatic pressure arises along the height of the second channel 56 during evacuation or venting.

As shown in FIG. 10, additional elements may be provided between the first channel 51 and the additional first channel 52 for homogenization of the gas flow. The overflow orifices 54 may be provided in a slotted plate 53a. A baffle plate 53b for diverting the gas flow may at least partially overlap the overflow orifices 54. The baffle plate 53b may be formed integrally with the slotted plate 53a or may be provided as a separate part distinct therefrom. The baffle plate 53b may be non-slotted.

Openings for connecting with an evacuation device for evacuating the chamber 30 or with a venting device for venting the chamber 30 may be provided at the additional first channel 52 and the additional second channel 57. These openings may be covered by the slotted plate 53a and/or the non-slotted baffle plate 53b towards the inside of the chamber 30 so that the inflowing gas enters the chamber 30 via the overflow orifices 54 and after being diverted at the baffle plate 53b and is thus decelerated altogether. The deceleration of the gas during venting may take place using the overflow orifice 54 and/or the baffle plate 53b. The evacuation device may comprise a pump. The venting device may comprise an inflow orifice for gas.

These characteristic features may also be used if the first channel 51 and the additional first channel 52 are arranged horizontally displaced relative to each other and/or if the second channel 56 and the additional second channel 57 are arranged horizontally displaced relative to each other.

The chamber 30 and the flow channel arrangement with channels 51, 52, 56, 57 is configured such that the gas flows occurring in the chamber 30 are never directed perpendicular to the substrates positioned on the substrate carrier 102.

The vacuum lock 10 may be configured to pump down the chamber 30 in two stages. For this purpose, the vacuum lock 10 may comprise a first pump valve 71 and a second pump valve 72. The first pump valve 71 and the second pump valve 72 may have different dimensions and may be controlled by a control (not shown) in a way that the first pump valve 71 and the second pump valve 72 are opened sequentially during evacuation in order to create different pressure change rates in the chamber 30. The first pump valve 71 and the second pump valve 72 may both communicate with the additional first channel 52. The first pump valve 71 may communicate with a first pump connection 61 which is disposed adjacent to the additional first channel 52 at the chamber 30. The second pump valve 72 may communicate with a second pump connection 62 which is disposed adjacent to the additional first channel 52 at the chamber 30.

If the chamber 30 is evacuated from two opposing sides, a corresponding arrangement with an additional first pump valve 76, an additional first pump connection 66, an additional second pump valve 77 and an additional second pump connection 67 may be provided at the opposing side of the chamber 30. The control may control the pump valves 71, 71 and the additional pump valves 76, 77 such that the second pump valve 72 and the additional second pump valve 77 are open at the same time during evacuation in a first time interval while the first pump valve 71 and the additional first pump valve 76 are closed. The second valves 72, 77 may have smaller dimensions than the first valves 71, 76 so that gentler initial pumping may be achieved. The control may control the pump valves 71, 72, 76, 77 in a way that the first pump valve 71 and the additional first pump valve 76 are open at the same time during evacuation in a second time interval while the second pump valve 72 and the additional second pump valve 77 are also open or closed.

The first pump valve 71 and the additional first pump valve 76 may have an identical configuration. The second pump valve 72 and the additional second pump valve 77 may have an identical configuration. Preferably, only one pump device by which the lock is evacuated from opposing sides of the chamber 30 is used. The connections between the pump device and the first pump valves 71, 76 and the second pump valves 72, 77 may be symmetric in order to achieve the same pumping capacity on both sides of the chamber 30. In this case, the sides may be the face sides or longitudinal sides of the chamber 30.

The pump valves may be connected with at least one pump via pump lines 63a, 63b, 68a, 68b and a junction. The pump, the first pump valve 71 and the additional first pump valve 76 may be configured to reduce the pressure in the interior of the chamber at a rate of at least 100 hPa/s, preferably of at least 300 hPa/s, further preferably of at least 300 hPa/s to 500 hPa/s upon evacuation during the second time interval.

The vacuum lock 10 may be configured to vent the chamber 30 in two stages. For this purpose, the vacuum lock 10 may comprise a first vent valve 73 and a second vent valve 74. The first vent valve 73 and the second vent valve 74 may have different dimensions and may be controlled by the control such that the first vent valve 73 and the second vent valve 74 are sequentially opened during venting in order to create different temporal pressure changes in the chamber 30. The first vent valve 73 and the second vent valve 74 may both communicate with the additional first channel 52 by means of a vent line 64. The first vent valve 73 and the second vent valve 74 may both communicate with the additional second channel 57 by means of an additional vent line 69. The control may control the vent valves 73, 74 such that the first vent valve 73 is open upon venting during a first time interval while the second vent valve 74 is closed. The control may control the vent valves 73, 74 such that the second vent valve 74 is open upon venting during a second time interval while the first vent valve 73 is closed. In an alternative embodiment, the first vent valve 73 and the second vent valve may both be opened upon venting during a second time interval.

Preferably, only one venting device is used to vent the chamber 30 from two sides. The connection between the first vent valve 73 and the additional first channel 52 as well as the connection between the first vent valve 73 and the additional first channel 57 may be symmetric in order to vent the chamber 30 from both sides of the chamber 30 at the same volume flow rate. The connection between the second vent valve 74 and the additional first channel 52 as well as the connection between the second vent valve 74 and the additional second channel 57 may be symmetric in order to vent the chamber 30 from both sides of the chamber 30 at the same volume flow rate. In this case, the sides may be the face sides or longitudinal sides of the chamber 30.

FIG. 11 shows a pneumatic circuit diagram of the vacuum lock 30. Differently dimensioned first pump valves 71, 76 and second pump valves 72, 77 as well as differently dimensioned first and second vent valves 73, 74 allow the chamber to be evacuated and vented in two stages. In this context, gas may flow in symmetrically at the opposing sides of the chamber during venting and be extracted at the opposing sides of the chamber during evacuation.

With respect to its fluid-dynamic properties, the system may be configured symmetrically. For this purpose, the connection lines between the first vent valve 73 and the opposing sides of the chamber 30 may be identical in length and diameter and be disposed symmetrically. The connection lines between the second vent valve 74 and the opposing sides of the chamber 30 may be identical in length and diameter and be disposed symmetrically.

Alternatively or additionally, the connection lines between the pump and the pump valves 71, 72 may have lengths and diameters identical to the connection lines between the pump and the additional pump valves 76, 77. The connection lines between the pump valves 71, 72 and a first side of the lock chamber may have lengths and diameters identical to the connection lines between the pump valves 76, 77 and a second side of the chamber 30 opposing the first side.

In this context, the sides of the chamber 30 may be the longitudinal sides or the face sides of the chamber 30.

FIG. 12 and FIG. 13 illustrate the mode of operation of the vacuum lock 10. FIG. 12 shows a velocity field 81, 82 of a gas flow at the first substrate carrier surface 21 during evacuation of the chamber 30. FIG. 13 shows a velocity field 83, 84 of the gas flow at the second substrate carrier surface 22 during evacuation of the chamber 30. Since gas is extracted at opposing sides via the first channel 51 and the second channel 56, a velocity field substantially mirror-symmetric to the center plane 90 of the chamber 30 is created. For any point on the first substrate carrier surface 21, the velocity 81, 82 of the gas flow has the same magnitude and direction as the velocity 83, 84 of the gas flow at the corresponding, opposing point of the second substrate carrier surface 22. Static differences in pressure are reduced or substantially eliminated.

The configuration of the flow channel arrangement leads to a velocity field that is homogeneous along a longitudinal direction 50 of the first channel 51 so that no pressure gradients are present parallel to the longitudinal direction 50 of the first channel 51 at the first substrate carrier surface 21 and the second substrate carrier surface 22. Undesired crossflows, which may lead to displacement of substrates at or in the substrate carrier 102, may thus be avoided.

The vacuum lock 10 reduces the risk of an undesired displacement of substrates relative to the substrate carrier 102 as well as damage to the substrates. For instance, a substrate carrier 102 loaded with 64 substrates may be inserted into the lock, which may quickly be evacuated or vented thereafter. The size of the substrate carrier 102 may be more than 2 m². Substrates, which may be Si wafers, may have a thickness of more than 100 μm, preferably of between 120 and 500 μm. At a thickness of 120 μm, this corresponds to a weight of approx. 10 g per wafer. For a wafer surface of 15.6×15.6 cm²=243 cm², the grammage is 10 g/243 cm²=0.041 g/cm². Thus, an overpressure of 4.1 Pa at the lower side of the wafer is enough to lift said wafer in the substrate carrier 102 when positioned perpendicularly to the Earth's gravity field. Furthermore, there must not be any overpressure at the first substrate carrier surface 21, as otherwise the waver might be destroyed by pressure force generated by the resulting difference in pressure between the upper and lower sides. In order to avoid this, the vacuum lock according to the invention guarantees the difference in pressure between the first and second substrate carrier surfaces 21, 22 to remain below 10 Pa, preferably below 5 Pa, further preferably below 4 Pa. Experiments show that venting times of 5 s are achievable in vacuum locks with volumes of 350 l. For this purpose, a pressure gradient of 350 hPa/s had been achieved in the initial phase of venting, which corresponds to a volume flow rate of 120 l/s. As the pressure approaches the external atmospheric pressure, the gradient may flatten to 100 hPa/s. Under these circumstances, in which a high temporal pressure change rate occurs, there was no movement of the wafers inserted into the substrate carrier 102 in the vacuum lock 10.

The continuous machine 100 with the vacuum lock 10, which may be used as inlet lock 110 and/or outlet lock 150, allows an efficient deposition of layers or layer systems of high quality to be performed. In combination with plasma-enhanced chemical vapor phase deposition, layer systems of high quality may be deposited particularly efficiently.

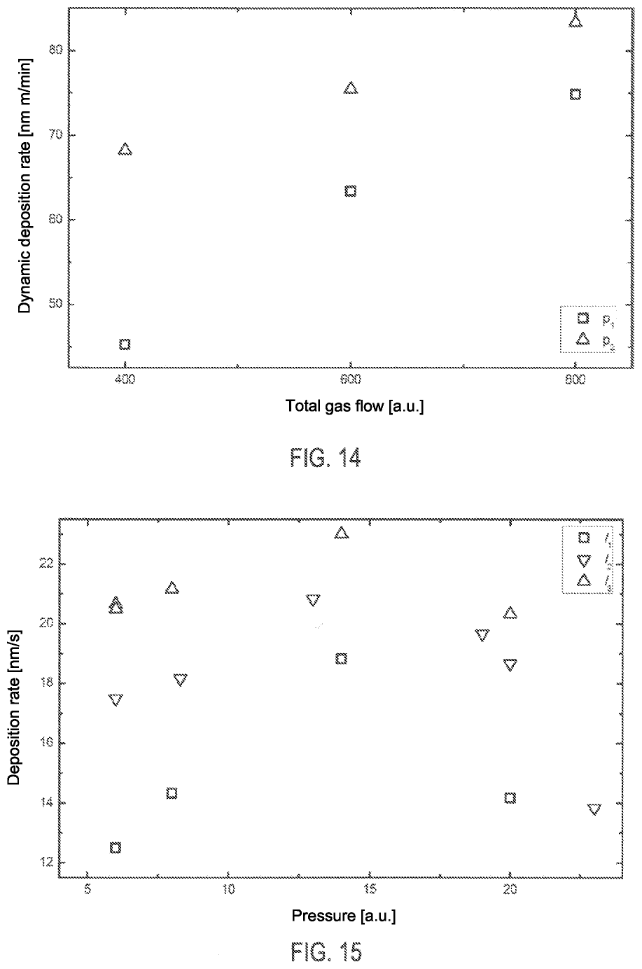

FIG. 14 shows a dynamic deposition rate of a SiNₓ:H antireflection coating on a monocrystalline silicon wafer as a function of the total gas flow of SiH₄ and NH₃ in the continuous machine according to an exemplary embodiment for different pressure rates of the process gases. A dynamic deposition rate of >20 nm m/min, preferably of >30 nm m/min, particularly preferably of >40 nm m/min and very particularly preferably of 50 to 80 nm m/min may be achieved.

FIG. 15 shows an average deposition rate of an SiNₓ:H antireflection layer on a monocrystalline silicon wafer in the continuous machine according to an exemplary embodiment as a function of the pressure for different gas flow rates. An average deposition rate of >4 nm/s, preferably of >5 nm/s and particularly preferably of >6 nm/s may be achieved.

The continuous machine may be configured for depositing silicon nitride. The continuous machine may comprise at least one process module for depositing silicon nitride.

The deposition of silicon nitride may take place at a dynamic deposition rate of >20 nm m/min, preferably of >30 nm m/min, particularly preferably of >40 nm m/min, and very particularly preferably of 50 to 80 nm m/min.

The deposition of silicon nitride may take place at an average deposition rate of >4 nm/s, preferably of >5 nm/s, and particularly preferably of >6 nm/s.

The deposition rate of silicon nitride may be varied and controlled by a gas flow rate of SiH₄ and NH₃, as illustrated in FIG. 14.

Alternatively or additionally, the deposition rate of silicon nitride may also be specifically influenced by the RF power.

The extension of the silicon nitride coating deposited by a plasma source parallel to the transport direction may be <50 cm, preferably <25 cm, particularly preferably <20 cm and very particularly preferably 5 to 20 cm. The extension of the coating parallel to the transport direction may be determined by the opening of the plasma source, particularly the location of the opening(s) of the gas distributors, and/or a screen perpendicular to the transport direction between the plasma source and the substrate carrier.

When depositing silicon nitride, the total gas flow rate per plasma source with respect to SiH₄ and NH₃ may range from 0.5 to 10 SLM (standard liters per minute), preferably from 3 to 8 SLM.

A deposition of SiNₓ:H layers may take place at a pressure range between >1 Pa and <100 Pa, preferably between 1 Pa to 60 Pa in the process area. The pressure rate in other regions of the process chamber may deviate by a factor 0.1-10 depending on the connection of the vacuum gauge head. For a given suction power of the vacuum generation device, the pressure present in the process area may be varied by changing the conductance (e.g., screens, restrictors).

A mass density of the SiNₓ:H layers may be controlled or regulated in closed-loop control by process parameters such as the temperature of the substrates and the RF power. The mass density may preferably lie within a range of 2.4 to 2.9 g/cm³.

A hydrogen content may be set by adjusting process parameters such as the RF power, the temperature of the substrates and the gas composition. The deposited SiNₓ:H layers may comprise a H content of >5%, preferably of >8%, particularly preferably of 8% to 20%.

The refractive index of the silicon nitride layer may be varied and controlled by the gas flow rate, particularly by the ratio of SiH₄ and NH₃. SiNₓ:H layers with a refractive index of 1.9 to 2.4 may be deposited.

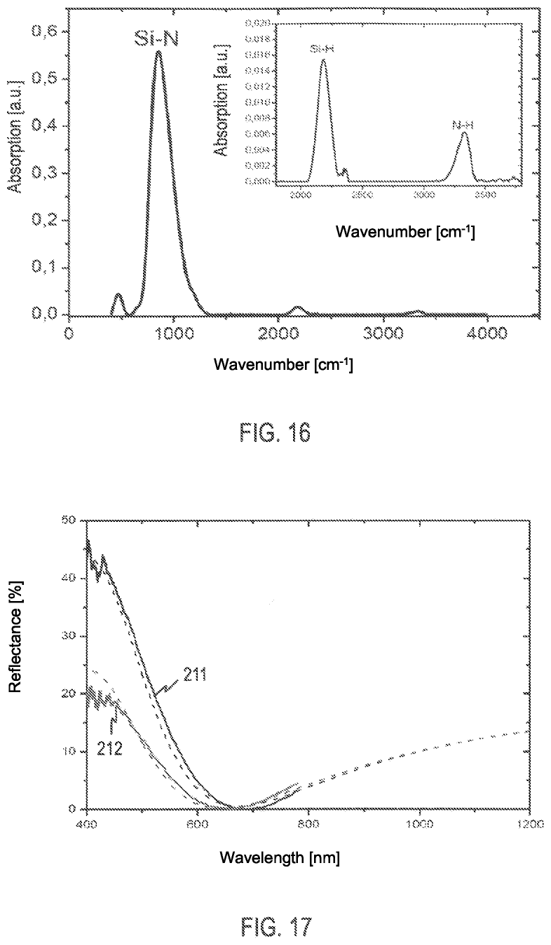

Fourier-transform infrared spectroscopy (FTIR) may be used for determining the bonds and bond densities in the silicon nitride layers. A typical absorption spectrum is illustrated in FIG. 16. In the range of wavenumbers of 600-1,300 cm⁻¹, the absorption of the [Si—N] bonds is visible. At wavenumbers of 2,050-2,300 cm⁻¹, the [Si—H] bonds are visible, and at wavenumbers of 3,200-3,400 cm⁻¹, the [N—H] bonds are visible.

In order to produce SiNx:H layers of satisfactory quality and having a satisfactory lifetime, the following preferred chemical composition with respect to the bonds and bond densities is preferred: [N—H] 3,350 cm⁻¹, [Si—H] 2,170-2,180 cm⁻¹ with bond densities of >5×10²¹ 1/cm³, preferably of 8-10×10²¹ 1/cm³, and [Si—N] 830-840 cm⁻¹ with bond densities of >100×10²¹ 1/cm³, preferably of >110×10²¹ 1/cm³, particularly preferably of >120×10²¹ 1/cm³.

For the deposition of SiNₓ:H layers having a satisfactory quality and a satisfactory lifetime, the temperature of the substrates may be below 600° C., preferably below 500° C., and particularly preferably range from 300 to 480° C.

Multi-layer systems of SiNₓ:H with different functions of the sublayers, e.g., for passivation and as an antireflection coating, may be realized by varying the process parameters at the individual plasma sources.

The continuous machine and the method according to exemplary embodiments allow an a-SiNₓ:H layer to be deposited as an antireflection coating, e.g., by means of a method for plasma-enhanced vapor phase deposition using an inductively coupled plasma source (ICP PECVD method). The desired dynamic deposition rates may be achieved with ICP PECVD methods.

For this purpose, an inductively coupled plasma source (ICP) may be used, which is stimulated by a radiofrequency (RF) generator, e.g., at a stimulation frequency within a range of 13 MHz to 100 MHz. The ICP source serves for generating a plasma at a length of >1,000 mm, preferably of >1,500 mm, particularly preferably of >1,700 mm. The RF generators may have a power of >4 kW, preferably of >6 kW, particularly preferably of 7 to 30 kW and very particularly preferably of 8 to 16 kW. The RF generator may be operated in a pulsed mode.

Amorphous SiNₓ:H films may be deposited using NH₃ as a reaction gas and SH₄ as a precursor.

The NH₃ may be introduced directly into the plasma chamber in order to generate a plasma jet of low energy (<20 eV). The SiH₄ may be introduced into the process in the vicinity of the substrate in order to form the SiNₓ:H film with the NHₓ plasma radicals. The substrates may be heated, e.g., by infrared radiation to temperatures of 300° C. to 480° C., e.g., of 300° C. to 400° C.

A parameter, by means of which the deposition rate may be controlled or regulated, is the total gas flow, as can be taken from FIG. 14 and FIG. 15. By changing the gas composition and temperature of the substrates, the properties of the deposited film (optical properties and mass density) may be held substantially constant for different total gas flows. An average deposition rate of >4 nm/s, preferably of >5 nm/s and particularly preferably of >6 nm/s may be achieved.

The mass density is an important parameter of the deposited film, which immediately affects the passivation properties of a-SiNₓ:H. The mass density may particularly be affected by the temperature of the substrates and the RF power. By means of adjusting these two parameters and the gas composition (NH₃/SiH₄), a mass density of 2.5 g/cm³ to 2.9 g/cm³ may be achieved without significantly affecting the optical properties of the deposited film.

The overall hydrogen content is related to the mass density and may be controlled or regulated similar to the mass density. The hydrogen content may be determined by FTIR.

With the use of another oxygen-containing process gas, suboxides or oxides, e.g., SiNₓO_{y}:H, a-SiₓO_{y}:H (i, n, p) and the like may also be deposited, which may be used as passivation, doting, tunnel and/or antireflection coatings on semiconductor substrates.

With the continuous machine and the method according to exemplary embodiments, reproducible thicknesses of a-SiNₓO_{y}:H layers on silicon cells may be achieved.

Alternatively or additionally to the deposition of silicon nitride, the continuous machine may be configured for depositing aluminum oxide. The continuous machine may comprise at least one process module for depositing aluminum oxide.

The deposition of aluminum oxide may be carried out at a dynamic deposition rate of >5 nm m/min, preferably of >8 nm m/min, particularly preferably of >10 nm m/min and particularly preferably of 10 to 20 nm m/min per plasma source.

The deposition of aluminum oxide may be carried out at an average deposition rate of >0.5 nm/s, preferably of >1.0 nm/s and particularly preferably of >1.4 nm/s.

The deposition rate of aluminum oxide may be varied and controlled by the total gas flow rate of an aluminum-containing precursor, e.g., (CH₃)₃Al, and an oxygen-containing reaction gas, e.g., N₂O. The deposition rate of aluminum oxide may also be specifically affected by the RF power.

The extension of the aluminum oxide coating deposited by a plasma source may be <50 cm, preferably <25 cm, particularly preferably <20 cm and very particularly 5 to 20 cm. The extension of the coating parallel to the transport direction may be determined by the opening of the plasma source, particularly the location of the opening(s) of the gas distributors, and/or the width of a screen perpendicular to the transport direction between the plasma source and the substrate carrier.

When depositing aluminum oxide, a total gas flow rate per plasma source for (CH₃)₃Al and N₂O may lie within a range of 0.5 to 10 SLM (standard liters per minute), preferably within a range of 3 to 8 SLM.

The refractive index of the aluminum oxide layer may be varied and controlled by the gas flow rate, particularly by the ratio of (CH₃)₃Al and N₂O.

AlOₓ:H layers having a refractive index of >1.57 may be deposited.

Further layer properties of the aluminum oxide layer may be:

Layer thickness: 4-30 nm, preferably 4-20 nm, further preferably 4-15 nm;

Defect state density: Dᵢₜ<2×10¹¹ cm⁻² eV⁻¹;

Negative fixed charge density at the boundary surface:

Q_{tot,f}=−4×10¹² cm⁻¹;

Recombination velocities: Sᵣₑₐᵣ<10 cm⁻¹;

The temperature of the substrates for the deposition of AlOₓ:H layers of satisfactory quality and a satisfactory lifetime may lie below 600° C., preferably below 500° C. and particularly preferably within a range of 200 to 400° C.

FIG. 17 shows the reflection spectrum 211 for an individual SiNₓ:H antireflection layer and the reflection spectrum 212 for a SiN/SiNO double layer, which have each been deposited with a method according to the invention by ICP PECVD. Numerically simulated data is illustrated in dashed lines.

While exemplary embodiments have been described with respect to the figures, additional and alternative features may be used in further exemplary embodiments. For instance, it is not necessarily required for a process module to comprise a plasma source. Planar magnetrons and tubular magnetrons as well as inductively and/or capacitively coupled or microwave-excited plasma sources may be used for different coating methods such as PVD (physical vapor phase deposition) or PECVD (plasma-enhanced chemical vapor gas deposition) or other plasma processes (e.g., activation, etching, cleansing, implantation). A layer system made of individual layers may be deposited without interrupting the vacuum, similarly as explained with respect to FIG. 5 and FIG. 6.

The continuous machine and the method may not only be used for producing PERX or other silicon cells by means of PECVD, applying an antireflection coating or passivation layer or carrying out physical vapor phase deposition (PVD) but also for applying transparent, conductive coatings such as TCO, ITO, AZO, etc., applying contacting layers, applying all-over metal coatings (e.g., Ag, Al, Cu, NiV) or for applying barrier layers, without being limited thereto.

The continuous machine may be configured as a platform for various pretreatment and coating processes so that basic constructive elements such as the vacuum lock, the transport device, the configuration of the chambers, the control and automatization are universally usable while the type of the plasma sources and vacuum pumps are adapted according to the specific use (e.g., magnetron sputtering or plasma-enhanced chemical vapor phase deposition (PECVD)).

The following list of aspects defines further exemplary embodiments of the invention:

Aspect 1: A continuous machine for coating substrates, comprising:

a process module or a plurality of process modules; and

a vacuum lock for introducing the substrates or removing the substrates, wherein the vacuum lock comprises a chamber for receiving a substrate carrier with a plurality of substrates.

Aspect 2: The continuous machine according to aspect 1, wherein the vacuum lock further comprises a flow channel arrangement for evacuating and venting the chamber, wherein the flow channel arrangement comprises a first channel for evacuating and venting the chamber and a second channel for evacuating and venting the chamber, wherein the first channel and the second channel are arranged at opposing sides of the chamber.

Aspect 3: The continuous machine according to aspect 1 or aspect 2, wherein at least one process module comprises a plasma source, a gas supply device for introducing a plurality of process gases via separated gas distributors, and at least one gas extraction device for extracting the process gases.

Aspect 4: The continuous machine according to aspect 3, wherein the at least one process module with the plasma source comprises a first gas extraction device whose extraction orifice is disposed along a conveying direction of the substrates upstream the plasma source, and a second gas extraction device whose extraction orifice is disposed along the conveying direction downstream the plasma source.

Aspect 5: The continuous machine according to aspect 3 or aspect 4, wherein the plasma source and the gas supply device are combined in one plant component that is demountable from the continuous machine as a module.

Aspect 6: The continuous machine according to any one of the preceding aspects, further comprising:

a transport device for continuously transporting a sequence of substrate carriers through at least one section of the continuous machine, and

a conveying module for conveying the substrate carrier between the vacuum lock and the transport device, wherein the conveying module is disposed between the vacuum lock and the process module or the process modules.

Aspect 7: The continuous machine according to aspect 6, wherein the conveying module comprises a heating device with temperature control, wherein optionally the heating device is configured to heat the substrates from both sides.

Aspect 8: The continuous machine according to aspect 6 or aspect 7, wherein

the vacuum lock is a vacuum lock for introducing the substrates, and the continuous machine further comprises a second vacuum lock for removing the substrates, wherein the second vacuum lock comprises:

a second chamber for receiving the substrate carrier, and

a second flow channel arrangement for evacuating and venting the second chamber, wherein the second flow channel arrangement comprises a third channel for evacuating and venting the second chamber and a fourth channel for evacuating and venting the second chamber, wherein the third channel and the fourth channel are disposed at opposing sides of the second chamber.

Aspect 9: The continuous machine according to aspect 8, wherein the continuous machine further comprises:

a second conveying device for conveying the substrate carrier from the transport direction to the discontinuously operating second vacuum lock.

Aspect 10: The continuous machine according to aspect 8 or aspect 9, wherein the continuous machine is configured to transport the substrates between the first vacuum lock and the second vacuum lock through the continuous machine without interrupting a vacuum.

Aspect 11: The continuous machine according to any of the preceding aspects, wherein the continuous machine comprises a plurality of process modules and at least one transfer chamber which is arranged between two process modules.

Aspect 12: The continuous machine according to aspect 11, wherein the transfer chamber is configured to convey the substrates between the two process modules.

Aspect 13: The continuous machine according to any one of the preceding aspects, wherein the continuous machine is configured to introduce a nitrogen-containing first process gas and a silicon-containing second process gas into a process module with a plasma source via separate gas distributors.

Aspect 14: The continuous machine according to aspect 13, wherein the continuous machine is configured to introduce an oxygen-containing third process gas and an aluminum-containing fourth process gas into an additional process module having an additional plasma source.

Aspect 15: The continuous machine according to aspect 13 or aspect 14, wherein the continuous machine is a continuous machine for producing solar cells, particularly for producing one of the following solar cells: PERC (“Passivated Emitter Rear Cell”) cells; PERT (“Passivated Emitter and Rear Cell with Totally Diffused Back Surface Field”) cells; PERL (“Passivated Emitter and Rear Cell with Locally Diffused Back Surface Field”) cells; heterojunction solar cells; solar cells with passivated contacts.

Aspect 16: The continuous machine according to aspect 13, wherein the continuous machine is a continuous machine for applying an antireflection coating.

Aspect 17: The continuous machine according to any one of the preceding aspects, wherein the continuous machine is a continuous machine for coating crystalline silicon wafers.

Aspect 18: The continuous machine according to any one of the preceding aspects, wherein the vacuum lock is configured such that a difference in pressure between substrate carrier surfaces of the substrate carrier is at most 10 Pa, preferably at most 5 Pa, particularly preferably at most 4 Pa, when a pressure change rate exceeds 100 hPa/s, preferably 300 hPa/s, while the chamber is being evacuated or vented.

Aspect 19: The continuous machine according to any one of the preceding aspects, which is configured to process at least 4,000 substrates per hour, preferably at least 5,000 substrates per hour.

Aspect 20: The continuous machine according to any one of the preceding aspects, wherein the cycle time of the continuous machine is less than 60 s, preferably less than 50 s, further preferably less than 45 s.

Aspect 21: The continuous machine according to any one of the preceding aspects, wherein an average transport velocity in the continuous machine is at least 26 mm/s, preferably at least 30 mm/s, further preferably at least 33 mm/s.

Aspect 22: The continuous machine according to any one of the preceding aspects, wherein an operating period for evacuating the vacuum lock is less than 25 s, preferably less than 20 s, further preferably less than 18 s.

Aspect 23: The continuous machine according to any one of the preceding aspects, wherein the chamber of the vacuum lock comprises an upper chamber part and a lower chamber part and a first and a second inner surface.

Aspect 24: The continuous machine according to aspect 23 when dependent on aspect 2, wherein the flow channel arrangement is configured to cause a gas flow both in a first region between the first inner surface and a first substrate carrier surface facing the first inner surface and in a second region between the second inner surface and a second substrate carrier surface facing the second inner surface.

Aspect 25: The continuous machine according to aspect 24, wherein a ratio of a first distance d1 between the first inner surface and the first substrate carrier surface to a length L of the substrate carrier is smaller than 0.1, preferably smaller than 0.05, further preferably smaller than 0.025.

Aspect 26: The continuous machine according to aspect 24 or aspect 25, wherein a ratio of a second distance d2 between the second inner surface and the second substrate carrier surface to a length L of the substrate carrier is smaller than 0.1, preferably smaller than 0.05, further preferably smaller than 0.025.

Aspect 27: The continuous machine according to any one of aspects 23 to 26, wherein the vacuum lock is configured such that a ratio of a first flow resistance between the substrate carrier and the first inner surface to a second flow resistance between the substrate carrier and the second inner surface is between 0.95 and 1.05, preferably between 0.97 and 1.03.

Aspect 28: The continuous machine according to any one of aspects 23 to 27, wherein a difference in pressure between the first substrate carrier surface and the second substrate carrier surface is at most 10 Pa, preferably at most 5 Pa, particularly preferably at most 4 Pa, when a pressure change rate in the chamber exceeds 100 hPa/s, preferably 300 hPa/s, while the chamber is being evacuated or vented.

Aspect 29: The continuous machine according to any one of aspects 23 to 28, wherein the substrate carrier is positioned between the first and second inner surface such that

|d₁−d₂|/max(d₁, d₂)<15%, preferably |d₁−d₂|/max(d₁, d₂)<8%,

wherein d₁ is a first distance between the first substrate carrier surface and the first inner surface, and d₂ is a second distance between the second substrate carrier surface and the second inner surface.

Aspect 30: The continuous machine according to any one of the preceding aspects when dependent on aspect 2, wherein the flow channel arrangement is configured to create a gas flow directed perpendicular to a longitudinal direction of the first channel in at least one region of a first substrate carrier surface and in at least one region of a second substrate carrier surface, and to prevent crossflows parallel to the longitudinal direction of the first channel in the first region and the second region.

Aspect 31: The continuous machine according to any one of the preceding aspects when dependent on aspect 2, wherein the first channel and the second channel are parallel to each other.

Aspect 32: The continuous machine according to any one of the preceding aspects when dependent on aspect 2, wherein the first channel and the second channel are arranged at face sides of the chamber of the vacuum lock.

Aspect 33: The continuous machine according to any one of the preceding aspects when dependent on aspect 2, wherein the first channel and the second channel are spaced apart from each other by at least one length of the substrate carrier.

Aspect 34: The continuous machine according to any one of the preceding aspects depending on aspect 2, wherein the first channel and the second channel are arranged mirror-symmetrically to each other with respect to a center plane of the chamber.

Aspect 35: The continuous machine according to any one of the preceding aspects when dependent on aspect 2, wherein the flow channel arrangement comprises an additional first channel in fluid communication with the first channel by means of at least one overflow orifice, and/or wherein the flow channel arrangement comprises an additional second channel in fluid communication with the second channel by means of at least one second overflow orifice.

Aspect 36: The continuous machine according to aspect 35, further comprising a device for homogenization of the flow between the first channel and the additional first channel, said device comprising at least one overflow orifice, wherein optionally the overflow orifice is smaller than a cross section of the additional first channel; and/or

further comprising a device for homogenization of the flow between the second channel and the additional second channel, said device comprising at least one second overflow orifice, wherein optionally the second overflow orifice is smaller than a cross section of the additional second channel.

Aspect 37: The continuous machine according to any one of the preceding aspects when dependent on aspect 2, wherein the flow channel arrangement is configured to create the gas flow during venting and/or evacuation of the chamber such that a pressure gradient in a direction parallel to the longitudinal direction of the at least one channel is minimized at a first substrate carrier surface and a second substrate carrier surface.

Aspect 38: The continuous machine according to any one of the preceding aspects when dependent on aspect 2, wherein the first channel and the second channel extend perpendicularly or parallel to a transport direction of the substrate carrier in the continuous machine.

Aspect 39: The continuous machine according to any one of the preceding aspects when dependent on aspect 2, wherein the continuous machine is configured to position the substrate carrier in a non-overlapping manner with the first channel and the second channel during venting and evacuation of the chamber.

Aspect 40: The continuous machine according to any one of the preceding aspects when dependent on aspect 2, wherein both the first channel and the second channel comprise an opening for a fluid connection with a venting device and/or evacuating device.

Aspect 41: The continuous machine according to any one of the preceding aspects when dependent on aspect 2, wherein the vacuum lock further comprises a gas baffle plate for diverting a gas flow against a wall of the chamber during venting.

Aspect 42: The continuous machine according to any one of the preceding aspects, wherein the vacuum lock further comprises at least one connecting branch for connecting with an evacuating device and/or a venting device.

Aspect 43: The continuous machine according to any one of the preceding aspects, wherein the continuous machine further comprises a valve arrangement which is provided between the chamber and the evacuating device and/or venting device.

Aspect 44: The continuous machine according to aspect 43, wherein the valve arrangement comprises a first valve and a second valve with different dimensions.

Aspect 45: The continuous machine according to aspect 44, wherein the continuous machine comprises a control for controlling the first valve and the second valve for two-stage venting or two-stage evacuation of the chamber.

Aspect 46: The continuous machine according to aspects 42 to 45, further comprising fluid connection lines configured symmetrically to each other between the evacuating device and opposing sides of the chamber and/or fluid connection lines configured symmetrically to each other between the venting device and opposing sides of the chamber.

Aspect 47: The continuous machine according to aspect 46, wherein the fluid connection lines connect the opposing sides of the chamber with a common evacuation device or with a common venting device.

Aspect 48: A method for coating substrates in a continuous machine which comprises a process module or a plurality of process modules, wherein the method comprises:

introducing the substrates into the continuous machine using a first vacuum lock,

treating the substrates in the process module or the process modules, and

removing the substrates from the continuous machine using a second vacuum lock,

wherein at least one of the first and second vacuum locks comprises a chamber for receiving a substrate carrier with substrates retained thereon.

Aspect 49: The method according to aspect 48, wherein the at least one of the first and second vacuum locks comprises a flow channel arrangement for evacuating and venting the chamber, wherein the flow channel arrangement comprises a first channel for evacuating and venting the chamber and a second channel for evacuating and venting the chamber, wherein the first channel and the second channel are arranged at opposing sides of the chamber.

Aspect 50: The method according to aspect 48 or aspect 49, wherein both the first vacuum lock and the second vacuum lock are configured such that a difference in pressure between substrate carrier surfaces of the substrate carrier is at most 10 Pa, preferably at most 5 Pa, particularly preferably at most 4 Pa, when a pressure change rate exceeds 100 hPa/s, preferably 300 hPa/s, while the chamber is being evacuated or vented.

Aspect 51: The method according to any one of aspects 48 to 50, wherein the substrates are crystalline silicon wafers.

Aspect 52: The method according to any one of aspects 48 to 51, wherein the continuous machine processes at least 4,000 substrates, particularly at least 5,000 substrates per hour.

Aspect 53: The method according to any one of aspects 48 to 52, wherein a cycle time of the continuous machine is less than 60 s, preferably less than 50 s, further preferably less than 45 s.

Aspect 54: The method according to any one of aspects 48 to 53, wherein an average transport velocity in the continuous machine is at least 26 mm/s, preferably at least 30 mm/s, further preferably at least 33 mm/s.

Aspect 55: The method according to any one of aspects 48 to 54, wherein an operating period of the vacuum lock is less than 25 s, preferably less than 20 s, further preferably less than 18 s.

Aspect 56: The method according to any one of aspects 48 to 55, wherein the chamber comprises an upper chamber part and a lower chamber part and a first and a second inner surface.

Aspect 57: The method according to aspect 56 when dependent on aspect 49, wherein the flow channel arrangement is configured to cause a gas flow both in a first region between the first inner surface and a first substrate carrier surface facing the first inner surface and in a second region between the second inner surface and a second substrate carrier surface facing the second inner surface.

Aspect 58: The method according to aspect 57, wherein a ratio of a first distance d1 between the first inner surface and the first substrate carrier surface to a length L of the substrate carrier is smaller than 0.1, preferably smaller than 0.05, further preferably smaller than 0.025.

Aspect 59: The method according to aspect 57 or aspect 58, wherein a ratio of a second distance d2 between the second inner surface and the second substrate carrier surface to a length L of the substrate carrier is smaller than 0.1, preferably smaller than 0.05, further preferably smaller than 0.025.

Aspect 60: The method according to any one of aspects 57 to 59, wherein a ratio of a first flow resistance between the substrate carrier and the first inner surface to a second flow resistance between the substrate carrier and the second inner surface is between 0.95 and 1.05, preferably between 0.97 and 1.03.

Aspect 61: The method according to any one of aspects 57 to 60, wherein a difference in pressure between the first substrate carrier surface and the second substrate carrier surface is at most 10 Pa, preferably at most 5 Pa, particularly preferably at most 4 Pa, when a pressure change rate in the chamber exceeds 100 hPa/s, preferably 300 hPa/s while the chamber is being evacuated or vented.

Aspect 62: The method according to any one of aspects 57 to 61, wherein the substrate carrier is positioned between the first and second inner surface such that

|d₁−d₂|/max(d₁, d₂)<15%, preferably |d₁−d₂|/max(d₁, d₂)<8%,

wherein d₁ is a first distance between the first substrate carrier surface and the first inner surface, and d₂ is a second distance between the second substrate carrier surface and the second inner surface.

Aspect 63: The method according to any one of aspects 57 to 62, wherein the flow channel arrangement is configured to create a gas flow directed perpendicular to a longitudinal direction of the first channel in at least one region of a first substrate carrier surface and in at least one region of a second substrate carrier surface, and to prevent crossflows parallel to the longitudinal direction of the first channel in the first region and the second region.

Aspect 64: The method according to any one of aspects 48 to 63, which is carried out by the continuous machine according to any one of aspects 1 to 47.

Different effects may be achieved with the continuous machines and methods according to exemplary embodiments. The quality of the deposited coating or layer systems on substrates may be improved. The productivity of the continuous machine may be increased. Introduction and removal times for substrate carriers with substrates may be so short they do not limit the throughput of the continuous machine.

When used for producing solar cells, the production costs for coating solar cells may be reduced. Highly efficient solar cells may be produced at low cost, which makes the solar cells more competitive for generating energy. Good passivation layers of the front surface and the rear surface may contribute to reduce recombination of the produced electrons or holes in the formed Si solar cells and prevent recombination of the charge carriers.

The continuous machine offers a scalable plant concept so that the required throughput and productivity may be achieved by adjusting the plant parameters. For instance, the widths of the continuous machine and the substrate carrier may be increased in order to allow for higher throughput. The vacuum lock or the vacuum locks of the continuous machine may be scalable so that they are adjustable to different throughputs of substrates. For this purpose, the width and/or length of the vacuum locks may be chosen according to the dimensions of the substrate carrier which is to be transferred in order to achieve the desired target volume.

A reduction of plant contamination may be achieved. This leads to an extension of the average time between maintenance works. The average maintenance interval may be reduced.

Exemplary embodiments of the invention may advantageously be used for coating wafers. The continuous machine according to the invention may, e.g., be a coating plant for rectangular or circular wafers, without being limited thereto.

1-27. (canceled)

28. A continuous machine for coating substrates, comprising:
a process module or a plurality of process modules; and
a vacuum lock for introducing the substrates or removing the substrates, wherein the vacuum lock comprises:
a chamber for receiving a substrate carrier with a plurality of substrates, and
a flow channel arrangement for evacuating and venting the chamber, wherein the flow channel arrangement comprises a first channel for evacuating and venting the chamber and a second channel for evacuating and venting the chamber, wherein the first channel and the second channel are arranged at opposing sides of the chamber.

29. The continuous machine according to claim 28, wherein at least one process module comprises a plasma source, a gas supply device for introducing a plurality of process gases via separated gas distributors and at least one gas extraction device for extracting the process gases.

30. The continuous machine according to claim 29, wherein the at least one process module with the plasma source comprises a first gas extraction device whose extraction orifice is arranged along a conveying direction of the substrates upstream the plasma source, and a second gas extraction device whose extraction orifice is arranged along a conveying direction of the substrates downstream the plasma source; and/or
wherein the plasma source and the gas supply device are combined in one machine component which is demountable from the continuous machine as a module.

31. The continuous machine according to claim 28, further comprising:
a transport device for continuously transporting a sequence of substrate carriers through at least one section of the continuous machine, and
a conveying module for conveying the substrate carrier between the vacuum lock and the transport device, wherein the conveying module is arranged between the vacuum lock and the process module or the plurality of process modules.

32. The continuous machine according to claim 31, wherein the conveying module comprises a temperature control device, wherein optionally the temperature control device comprises a heating device in order to heat the substrates from both sides.

33. The continuous machine according to claim 31, wherein the vacuum lock is a vacuum lock for introducing the substrates, and the continuous machine further comprises a second vacuum lock for removing the substrates, wherein the second vacuum lock comprises:
a second chamber for receiving the substrate carrier, and
a second flow channel arrangement for evacuating and venting the second chamber, wherein the second flow channel arrangement comprises a third channel for evacuating and venting the second chamber and a fourth channel for evacuating and venting the second chamber, wherein the third channel and the fourth channel are arranged at opposing sides of the second chamber.

34. The continuous machine according to claim 33, wherein the continuous machine further comprises:
a second conveying module for conveying the substrate carrier from the transport device to the discontinuously operating second vacuum lock; and/or
wherein the continuous machine is configured to transport the substrates between the first vacuum lock and the second vacuum lock through the continuous machine without interrupting a vacuum.

35. The continuous machine according to claim 28, wherein the continuous machine comprises a plurality of process modules and at least one transfer chamber arranged between two process modules;
optionally wherein the transfer chamber is configured for transferring the substrates between the two process modules.

36. The continuous machine according to claim 28, wherein the continuous machine is configured to introduce a nitrogen-containing first process gas and a silicon-containing second process gas into a process module having a plasma source via separate gas distributors.

37. The continuous machine according to claim 36, wherein the continuous machine is configured to introduce an oxygen-containing third process gas and an aluminum-containing fourth process gas into an additional process module having a further plasma source; and/or
wherein the continuous machine is a continuous machine for producing solar cells, particularly for producing one of the following solar cells:
PERC (“Passivated Emitter Rear Cell”) cells;
PERT (“Passivated Emitter and Rear Cell with Totally Diffused Back Surface Field”) cells;
PERL (“Passivated Emitter and Rear Cell with Locally Diffused Back Surface Field”) cells;
heterojunction solar cells;
solar cells with passivated contacts.

38. The continuous machine according to claim 36, wherein the continuous machine is a continuous machine for applying an antireflection coating and/or a passivation layer.

39. The continuous machine according to claim 28, wherein the vacuum lock is configured such that a difference in pressure between front and rear surfaces of the substrates and the substrate carrier is at most 10 Pa, preferably at most 5 Pa, particularly preferably at most 4 Pa, when a pressure change rate exceeds 100 hPa/s, preferably 300 hPa/s, while the chamber is being evacuated or vented.

40. The continuous machine according to claim 28, wherein the continuous machine is a continuous machine for coating crystalline silicon wafers; and/or
wherein the continuous machine is configured to process at least 4,000 substrates per hour, preferably at least 5,000 substrates per hour.

41. The continuous machine according to claim 28, wherein a cycle time of the continuous machine is shorter than 60 s, preferably shorter than 50 s, further preferably shorter than 45 s, and/or
wherein an average transport velocity in the continuous machine and/or in the process module is at least 25 mm/s, preferably at least 30 mm/s, further preferably at least 33 mm/s.

42. The continuous machine according to claim 28, wherein an operating time for evacuating the vacuum lock is shorter than 25 s, preferably shorter than 20 s, further preferably shorter than 18 s, and/or wherein an operating time for venting the vacuum lock is shorter than 16 s, preferably shorter than 10 s, further preferably shorter than 6 s.

43. The continuous machine according to claim 28, wherein at least one process module comprises a sputter cathode.

44. A method for coating substrates in a continuous machine, said continuous machine comprising a process module or a plurality of process modules, wherein the method comprises:
introducing the substrates into the continuous machine using a first vacuum lock,
treating the substrates in the process module or the process modules, and
removing the substrates from the continuous machine using a second vacuum lock,
wherein at least one of the first and second vacuum locks comprises the following:
a chamber for receiving a substrate carrier with substrates retained thereon, and
a flow channel arrangement for evacuating and venting the chamber, wherein the flow channel arrangement comprises a first channel for evacuating and venting the chamber and a second channel for evacuating and venting the chamber, wherein the first channel and the second channel are arranged at opposing sides of the chamber.

45. The method according to claim 44, wherein both the first vacuum lock and the second vacuum lock are configured such that a difference in pressure between substrate carrier surfaces of the substrate carrier are at most 10 Pa, preferably at most 5 Pa, particularly preferably at most 4 Pa, when a pressure change rate exceeds 100 hPa/s, preferably 300 hPa/s, while the chamber is being evacuated or vented.

46. The method according to claim 44, wherein the substrates are crystalline silicon wafers; and/or
wherein the method is used for producing solar cells, particularly for producing one of the following solar cells:
PERC (“Passivated Emitter Rear Cell”) cells;
PERT (“Passivated Emitter and Rear Cell with Totally Diffused Back Surface Field”) cells;
PERL (“Passivated Emitter and Rear Cell with Locally Diffused Back Surface Field”) cells;
heterojunction solar cells;
solar cells with passivated contacts.

47. The method according to claim 44, which is carried out by the continuous machine which further comprises the first vacuum lock for introducing the substrates and the second vacuum lock for removing the substrates.
